(19) United States
(12) Patent Application Publication
(10) Pub. No.: US 2025/0275485 A1
(43) Pub. Date: Aug. 28, 2025

(54) SEMICONDUCTOR DEVICE PACKAGE WITH INTEGRAL HEAT SLUG AND ISOLATION

(71) Applicant: Texas Instruments Incorporated, Dallas, TX (US)

(72) Inventors: Chu-Yun Lo, Taipei City (TW); Chia-Wei Chang, Taipei City (TW); Hank Sung, Sachse, TX (US)

(21) Appl. No.: 18/589,820

(22) Filed: Feb. 28, 2024

(51) Int. Cl. H10N 52/80; H01L 21/48; H01L 21/56; H01L 23/00; H01L 23/31; H01L 23/495; H10N 52/01

(52) U.S. Cl. CPC H10N 52/80; H01L 21/4825; H01L 21/56; H01L 23/3107; H01L 23/49544; H01L 23/49568; H01L 24/40; H01L 24/48; H01L 24/84; H01L 24/85; H10N 52/01; H01L 2224/40175; H01L 2224/48175; H01L 2224/84; H01L 2224/85

(57) ABSTRACT

A described example includes: a leadframe having a high voltage section and a low voltage section spaced from and electrically isolated from the high voltage section, and a heat slug mounted to the high voltage section. The high voltage section includes an input portion connected to the heat slug at an interior end by a mount portion, and further includes an interior lead portion that is connected to the mount portion by a flexible connect portion. An insulating material mounted to the heat slug provides a die mount area for a semiconductor die having a Hall element that is positioned so that the Hall element is proximate to the heat slug. Mold compound covers the semiconductor die, portions of the leadframe, and portions of the heat slug while a board side surface of the heat slug is exposed forming a thermal pad for a semiconductor device package.

### TECHNICAL FIELD

This disclosure relates generally to semiconductor device packages with semiconductor dies and integral heat slugs.

### BACKGROUND

Semiconductor devices for magnetic sensing include Hall effect sensors with additional circuitry. Magnetic sensing can be used for motor control, position sensing, automation, current sensing and other applications. Hall effect sensors integrated in semiconductor devices can be formed by doping regions to include carriers that are sensitive to a magnetic field. A voltage proportional to a magnetic field is output by the Hall sensor while a current is applied to the Hall sensor in the presence of a magnetic field. The Hall sensor is most sensitive to magnetic fields normal to a plane in the Hall sensor.

Hall effect current sensing is increasingly used in the control of high voltage motors and in power systems. Sensing of currents of greater than 10 Amperes and up to 100 Amperes and more is increasingly needed. In addition, high voltages such as 100 Volts and up to 1000 Volts may be applied to the sensor. Solutions for semiconductor devices with Hall sensors for these applications currently involve expensive, combined, and/or bulky semiconductor packages. Examples include package-in-package solutions, where a packaged Hall sensor semiconductor device is placed in a second module with a magnetic core, and the components are again packaged. Other known solutions use custom semiconductor packages for Hall sensors. Non-standard footprints for the packaged semiconductor devices including Hall sensors increase board and system assembly costs.

The signal being sensed in a current sensor application may be a high voltage signal, for example of 50-800 Volts or even more. In an example approach that uses galvanic isolation in a semiconductor device package, the high voltage signal where current is being sensed can be coupled to leads of a leadframe that provide a conductive current path through an integral heat slug. The integral heat slug provides thermal dissipation out of the semiconductor device package and also provides a low resistance current path that routes current from the high voltage signal through the semiconductor device package and proximate to a Hall element on a semiconductor die, while the semiconductor die remains electrically isolated from the high voltage signal. The Hall element forms a sensor on the semiconductor die that can sense a magnetic field corresponding to the current flowing through the integral heat slug. Using bias circuitry to control the Hall element, the semiconductor die forms a current sensor that measures current flowing through the integral heat slug by sensing the magnetic field. The integral heat slug can be formed using a relatively thick conductor material that provides high thermal transfer to dissipate heat from the semiconductor device package, and which also provides a low resistance conductive path for the current through the semiconductor device package.

In an example approach, a heat slug can be used that has a C-shaped or U-shaped current path that couples an input portion coupled to input terminals to an output portion coupled to output terminals. A leadframe provides input and output terminals on multiple leads that extend outside the body of the semiconductor device package. The semiconductor device package can be formed using electronic mold compound (sometimes referred to as “EMC”) that is applied in a transfer mold to surround the leadframe, the heat slug and a semiconductor die positioned within the package. The leadframe can be mounted to a top side surface of the heat slug, for example it can be brazed, soldered or welded.

During a transfer molding operation to form a molded package for the elements, the heat slug, which can be a thick conductor material such as copper or copper alloy, can be physically displaced by the flow of liquid mold compound into a mold. Because the leadframe is also mounted to the heat slug, the leadframe leads may also move and can become misaligned, resulting in a defect or in a scrapped device. Even if the leads are not misaligned, a defect can form where the leads extend through and bond to the mold compound, resulting in delamination or package cracking either during production, or when in use. A reliable and robust semiconductor device package with galvanic isolation and an integral heat slug is needed.

### SUMMARY

In a described example, a method of forming a semiconductor device package includes attaching a heat slug to a high voltage section of leadframe that has a low voltage section spaced from and electrically isolated from the high voltage section. The high voltage section further includes an input portion with a mount portion at an interior end that is attached to an input portion of the heat slug, and the input portion of the high voltage section further includes an interior lead portion connected to the mount portion by a flexible connect portion. The high voltage section further includes an output portion spaced from the input portion with another mount portion at an interior end that is attached to an output portion of the heat slug, and the output portion further includes another interior lead portion coupled to another mount portion by another flexible connect portion. The heat slug further includes a heat slug connect portion positioned between and electrically coupling the input portion of the heat slug and the output portion of the heat slug. The method includes mounting an insulating material to the heat slug providing a die mount area; and mounting a semiconductor die on the die mount area with a portion of the semiconductor die including at least one Hall element that is placed proximate to the heat slug. The method continues by forming electrical connections of wire bonds or ribbon bonds between bond pads of the semiconductor die and leads of an interior lead portion of the low voltage section of the leadframe; and covering the electrical connections, the semiconductor die, and portions of the leadframe with mold compound to form a body for the semiconductor device package, while at least a portion of the heat slug is exposed from the mold compound forming a thermal pad for the semiconductor device package.

In another described example, an apparatus includes: a leadframe having a board side surface and an opposite top surface, the leadframe having a high voltage section and a low voltage section spaced from and electrically isolated from the high voltage section, and a heat slug mounted to the high voltage section. The heat slug has an input portion and an output portion spaced from the input portion and coupled to the input portion by a heat slug connect portion. The high voltage section of the leadframe includes an input portion connected to the input portion of the heat slug at an interior end by a mount portion, the input portion of the leadframe further including an interior lead portion that is connected to the mount portion by a flexible connect portion. The high voltage section of the leadframe has an output portion connected to the output portion of the leadframe at an interior end by another mount portion, the output portion of the high voltage section of the leadframe further including another interior lead portion that is connected to another mount portion by another flexible connect portion. The apparatus further includes an insulating material mounted to the leadframe and providing a die mount area for a semiconductor die; and a semiconductor die having a Hall element mounted to the die mount area and positioned so that the Hall element is proximate to the heat slug connect portion. Electrical connections of wire bonds or ribbon bonds are formed between bond pads of the semiconductor die and leads of an interior lead portion of the low voltage section of the leadframe. Mold compound covers the electrical connections, the semiconductor die, portions of the leadframe, while a portion of the heat slug is exposed from the mold compound forming a thermal pad for a semiconductor device package.

In a further described example, a Hall current sensor device includes: a leadframe having a board side surface and an opposite top surface, the leadframe having a high voltage section and a low voltage section spaced from and electrically isolated from the high voltage section. A heat slug is mounted to the high voltage section, the heat slug having an input portion and an output portion spaced from the input portion and coupled to the input portion by a heat slug connect portion. The high voltage section of the leadframe has an input portion connected to the input portion of the heat slug at an interior end by a mount portion, the input portion of the leadframe further includes an interior lead portion that is connected to the mount portion by a flexible connect portion. The high voltage section of the leadframe has an output portion connected to the output portion of the leadframe at an interior end by another mount portion, the output portion of the high voltage section of the leadframe further includes another interior lead portion that is connected to another mount portion by another flexible connect portion. Insulating material is mounted over the leadframe forming a die mount area for a semiconductor die. A semiconductor die having a Hall element is mounted to the die mount area, the semiconductor die having bond pads on a device side surface. Electrical connections including wire bonds or ribbon bonds are between the bond pads of the semiconductor die and the second set of leads on the low voltage section of the leadframe. Mold compound covers the electrical connections, the semiconductor die, portions of the leadframe, the first magnetic shield, and the second magnetic shield, while a portion of the heat slug is exposed from the mold compound forming a thermal pad for a semiconductor device package.

### BRIEF DESCRIPTION OF THE DRAWINGS

FIGS. 1A-AB illustrate, in projection views, a semiconductor wafer and an individual semiconductor die, respectively. FIG. 1C illustrates, in a circuit block diagram, an example application for a current sensor of an arrangement.

FIGS. 2A-2B illustrate, in projection views from a top side surface and a board side surface, respectively, a semiconductor device package that can be used with an arrangement.

FIGS. 3A-3B illustrate, in a cross-sectional view and a projection view, respectively, a semiconductor device package of an arrangement.

FIGS. 4A,4AA, 4B-4D, and FIGS. 4E-4EE illustrate, in a series of plan views and side views, selected steps for forming a semiconductor device package of an example arrangement. FIG. 4F illustrates, in a plan view, a leadframe array including molded semiconductor device packages of an arrangement arranged in rows and columns. FIGS. 4G-4GG illustrate, in a projection view and a corresponding close-up view, further details of the example arrangement of FIGS. 4A-4D. FIG. 4H illustrates, in a plan view, portions of an alternative example arrangement. FIG. 4I illustrates, in a close-up projection view, details of the alternative example arrangement of FIG. 4H. FIG. 4J illustrates an end view of a portion of the alternative example arrangement of FIG. 4H positioned in a mold tool used in a molding process.

FIGS. 5A-5D illustrate, in cross-sectional and projection views, details of an alternative example semiconductor device package of an arrangement.

FIG. 6 illustrates in a plan view a simulation result showing mechanical stress during molding for a leadframe incorporating the arrangements.

FIG. 7 illustrates, in a flow diagram, an example method for forming an arrangement.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor die” is used herein. A semiconductor die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor die can include passive devices such as resistors, inductors, filters, sensors, or active devices such as transistors. The semiconductor die can be an integrated circuit with hundreds or thousands of transistors coupled to form a functional circuit, for example a microprocessor or memory device.

The term “semiconductor device package” is used herein. A semiconductor device package has at least one semiconductor die electrically coupled to terminals, and has a package body that protects and covers the semiconductor die. In some arrangements, multiple semiconductor dies can be packaged together. For example, a power metal oxide semiconductor (MOS) field effect transistor (FET) semiconductor die and a logic semiconductor die (such as a gate driver die or a controller die) can be packaged together to from a single packaged electronic device. Additional components such as passives can be included in the packaged electronic device. The semiconductor die is mounted to a package substrate that provides conductive leads; a portion of the conductive leads form the terminals for the packaged device. The semiconductor die can be mounted to the package substrate with a device side surface facing away from the substrate and a backside surface facing and mounted to a die pad of the package substrate. In wire bonded semiconductor device packages, wire bonds couple conductive leads of a package substrate to bond pads on the semiconductor die. The semiconductor device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the terminals for the semiconductor device package.

The term “package substrate” is used herein. A package substrate is a substrate arranged to receive a semiconductor die and to support the semiconductor die in a completed semiconductor device package. Package substrates useful with the arrangements include conductive leadframes, which can be formed from copper, aluminum, stainless steel, steel and alloys such as Alloy 42 and copper alloys. The leadframes can be provided in strips or arrays. The conductive leadframes can be provided as a panel with strips or arrays of unit device portions in rows and columns. Semiconductor dies can be placed on respective unit device portions within the strips or arrays. A semiconductor die can be placed on a die mount area for each packaged device, and die attach or die adhesive can be used to mount the semiconductor dies to the die mount areas. In wire bonded packages, bond wires can couple bond pads on the semiconductor dies to the leads of the leadframes. The leadframes may have plated portions in areas designated for wire bonding, for example silver plating can be used. After the bond wires are in place, a portion of the package substrate, the semiconductor die, and at least a portion of the die pad can be covered with a protective material such as a mold compound. The terminals formed from the leads extending from the mold compound can be plated to make the ends of the terminals more solderable, plating such as tin or nickel plating can be applied either prior to use of the leadframe (“pre-plated”) or after device molding (“post-plated”).

In the example arrangements, a leadframe with isolated portions can be used. The leadframe has a high voltage portion with a first set of leads forming terminals configured for coupling to high voltage signals or supplies, such as at voltages greater than 20 Volts and up to several hundred volts. The leadframe has a low voltage portion with a second set of leads forming terminals configured for coupling to low voltage signals such as logic level signals at voltages of less than 20 Volts. The high voltage portion and the low voltage portion are isolated electrically from one another.

In packaging semiconductor devices, epoxy mold compound (EMC) may be used to partially cover a package substrate, to cover the semiconductor die, and to cover the electrical connections from the semiconductor die to the package substrate. This can be referred to as an “encapsulation” process, although some portions of the package substrates are not covered in the mold compound during encapsulation, for example leads forming terminals are exposed from the mold compound, and thermal pads can be exposed from the mold compound.

Encapsulation is often a compressive molding process, where thermoset mold compound such as an epoxy resin can be used. A room temperature solid or powder mold compound can be heated to a liquid state, and then molding can be performed by pressing the liquid mold compound into a mold. Transfer molding can be used. Unit molds shaped to surround an individual device may be used, or block molding may be used, to form the packages simultaneously for several devices from mold compound. The devices can be provided in an array of several, hundreds or even thousands of devices in rows and columns that are to be molded simultaneously. After the molding, the individual packaged devices are cut from each other in a sawing operation by cutting through the mold compound and package substrate in saw streets formed between the devices. Portions of the package substrate leads are exposed from the mold compound package to form the terminals for the packaged semiconductor device.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel and normal to the length of the strip. When the molded electronic devices are provided in an array of devices in rows and columns, the saw streets include two groups of parallel saw streets, the two groups are normal to each other and the saw will traverse the molded electronic devices in two different directions to cut apart the packaged electronic devices from one another in the array.

The term “quad flat no-lead” or “QFN” is used herein for a type of electronic device package. A QFN package has conductive leads that are coextensive with the sides of a molded package body, and in a quad package the leads are on four sides. Alternative flat no-lead packages may have leads on two sides or only on one side. These can be referred to as “small outline no-lead” or “SON” packages. No-lead packaged electronic devices can be surface mounted to a board. Leaded packages can be used with the arrangements where the leads extend away from the package body and are shaped to form a portion for soldering to a board. A dual in-line package (“DIP”) can be used with the arrangements. A small outline package (SOP) can be used with the arrangements. Small outline no-lead (SON) packages can be used, and a small outline transistor (SOT) package is a leaded package that can be used with the arrangements. Leads for leaded packages are arranged for solder mounting to a board. The leads can be shaped to extend towards the board, and form a mounting surface. Gull wing leads, J-leads, and other lead shapes can be used. A small outline integrated circuit (SOIC) package with leads can be used with the arrangements. “Wide SOIC” packages with a larger package body width can be used with the arrangements. Dual in-line packages (DIPs) can be used. In DIPs, the leads end in pin shaped portions that can be inserted into conductive holes formed in a circuit board, and solder is used to couple the leads to the conductors within the holes.

The term “magnetic material” is used herein. A magnetic material useful with the arrangements includes iron oxide, Fe₂O₃, useful examples include nickel ferrite (NiFe), nickel zinc ferrite (NiZnFe), and manganese zinc ferrite (MnZnFe). Ferrites are ferrimagnetic, and become magnetized in the presence of a magnetic field. The term “magnetic concentrator” is used herein. A magnetic concentrator is a piece of magnetic material positioned to focus a magnetic field on a sensor. In an example arrangement, magnetic concentrators can be placed over a semiconductor die with an internal Hall element that is sensitive to magnetic fields.

The term “heat slug” is used herein. A heat slug is a conductor material that conducts heat. In the arrangements a heat slug is used to provide a low resistance path to carry a current. The heat slug is mounted to and electrically coupled to a high voltage portion of a leadframe and forms part of a current path between an input terminal or terminals and an output terminal or terminals in the high voltage portion of the leadframe. The terminals are arranged to be coupled to a high voltage at the input terminal and to carry the current. The heat slug in the arrangements can have a heat slug connect portion that is a “C” shaped, “U” shaped, “D” shaped or “V” shaped conductor from a plan view. Because the heat slug is included inside a semiconductor device package, the heat slug is referred to herein as an “integral heat slug.” The integral heat slug carries the current to a position within the semiconductor package that is proximate to a semiconductor die that includes a Hall element (or multiple Hall elements). The Hall element operates by sensing the magnetic field generated by the current flowing through the heat slug. In an example arrangement a copper heat slug that is thicker than the leadframe is used, and the copper heat slug can have a board side surface that is exposed from a mold compound body of the semiconductor device package to form one or more thermal pads for transferring heat from the semiconductor device package.

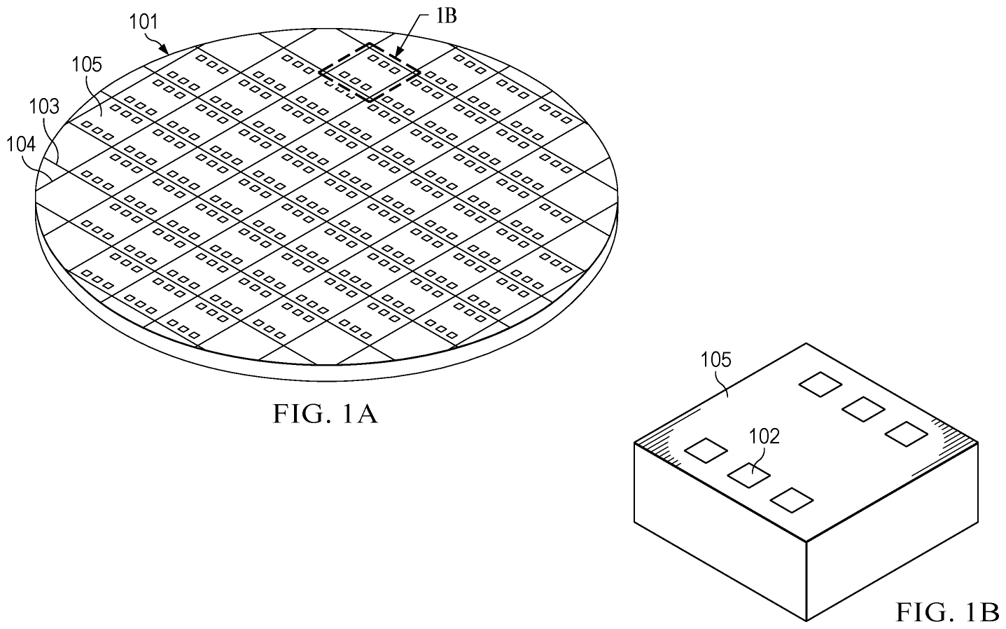

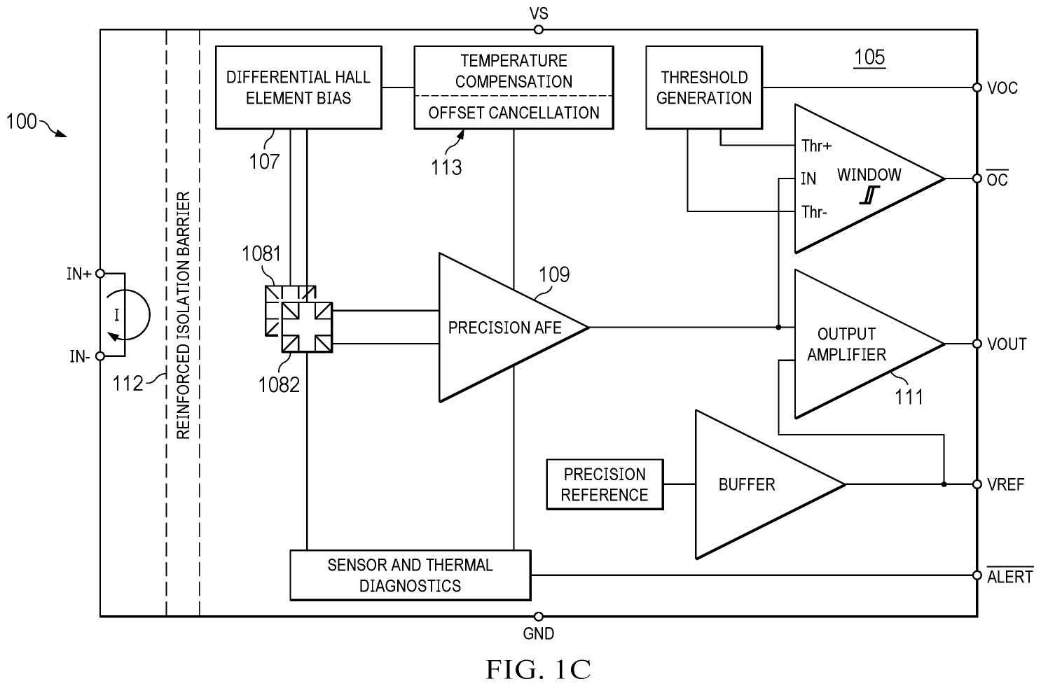

FIGS. 1A-1B illustrate steps used in forming semiconductor dies such as used with the arrangements for wire bonding. In FIG. 1A, a semiconductor wafer 101 is shown with an array of semiconductor dies 105 arranged in rows and columns.

The semiconductor dies 105 are formed using manufacturing processes in a semiconductor manufacturing facility, including ion implantation for carrier doping, thermal anneals, oxidation, dielectric and conductor deposition, photolithography, pattern, etch, chemical mechanical polishing (CMP), electroplating, and other processes for making semiconductor devices. Devices are formed on a device side surface of the semiconductor dies. Scribe lanes 103 and 104, which are perpendicular to one another and which run in parallel groups across the semiconductor wafer 101, separate the rows and columns of the completed semiconductor dies 105, and provide areas for dicing the wafer to separate the semiconductor dies 105 from one another. The reference label “1B” in FIG. 1A indicates a single semiconductor die 105 on the semiconductor wafer 101 that is shown in FIG. 1B.

FIG. 1B illustrates the single semiconductor die 105 in a projection view, with bond pads 102, which are conductive pads that are electrically coupled to devices (not shown for simplicity) formed in semiconductor die 105. The semiconductor dies 105 on semiconductor wafer 101 are separated from semiconductor wafer 101 by wafer dicing, or are singulated from one another, using the scribe lanes 103, 104 (see FIG. 1A). Wafer dicing can be done by a mechanical saw, by laser cutting or laser stealth dicing along the scribe lanes, or by plasma dicing. The semiconductor die 105 shown in FIG. 1B includes a Hall element (not shown), or more than one Hall element. In an example arrangement the Hall element(s) are configured as part of a current sensor.

FIG. 1C is a circuit block diagram for an example semiconductor device 100 that can be used in an arrangement. The circuit block diagram illustrates a circuit implemented on a semiconductor die 105. The example semiconductor device 100 is a Hall current sensor. The semiconductor device 100 includes an isolation barrier 112 that uses galvanic isolation to isolate high voltage signals (for example, signals at voltages from 20V up to several hundred volts or higher) from a semiconductor die 105 within a semiconductor device package, and to electrically isolate the high voltage signals (IN+, IN− in FIG. 1C) from low voltage signals (such as logic level voltage signals between 0.5-20 Volts, for example the output voltage signal VOUT in FIG. 1C) that are coupled to or are output by the semiconductor device 100. The semiconductor device 100 can be implemented as a semiconductor die such as semiconductor die 105 in FIG. 1B.

Referring to the semiconductor device 100 of FIG. 1C, in an example application, an input IN+ can be coupled to a first node and can receive a signal carrying a current labeled “I”, for example the node at IN+ may be coupled to a high voltage signal or high voltage supply, and an output IN− can be coupled to a second node, output IN− that outputs the current I. A semiconductor die (see, for example semiconductor die 105 in FIG. 1B) within semiconductor device 100 includes at least one Hall element, in the illustrated example two Hall elements, a first Hall element 1081, and a second Hall element 1082, are shown. Circuitry needed to control and monitor the first and second Hall elements 1081, 1082 are provided, including a Differential Hall Element Bias circuit 107, a Temperature Compensation and Offset Cancellation circuit 113, a Precision Analog Front End (AFE) 109, and an Output Amplifier 111. Other circuitry to increase device reliability and performance, such as overvoltage, overcurrent, and temperature sensors with corresponding control and output signals, can be provided in semiconductor die 105.

In operation, the output amplifier 111 drives an output voltage signal VOUT that corresponds to the magnitude of the current I, or which changes voltage with variations in the current I. A magnetic field that occurs due to the current I is sensed by the Hall elements 1081, 1082, and the output voltage signal VOUT corresponding to the magnitude of the magnetic field is output by semiconductor die 105. In a system, a calibration scheme can be used to determine a value of the current I from the voltage signal that appears at the output VOUT. An isolation barrier 112 is shown, the isolation barrier 112 is formed by use of a package substrate with isolated portions to mount the semiconductor die within a magnetic field that occurs due to current I, while keeping the semiconductor die electrically isolated from the high voltage signals at the input IN+ and the output IN− where the current I is supplied. The semiconductor die 105 can be of a material or materials that cannot withstand the high voltage applied at the terminal IN+, and in an example arrangement can be made of silicon and can operate at lower voltages, such as 10 Volts or less. This aspect of the arrangements reduces costs of the Hall current sensor device 100 and allows use of conventional semiconductor processing to form the semiconductor die 105. While in the illustrated example of FIG. 1C, two Hall elements 1081, 1082 spaced apart are used, and the semiconductor device uses differential sensing by a precision analog amplifier 109, in an alternative arrangement a single Hall element can be used. The illustrated example arrangement of FIG. 1C allows for common mode noise reduction by using differential sensing to remove common noise sensed by both Hall elements 1081, 1082 from the output signal by simply sensing a differential signal in the precision AFE 109. In an example common noise rejection is achieved by differential sensing to remove noise that appears at both Hall elements 1081, 1082. In additional arrangements, more than two Hall elements can be used.

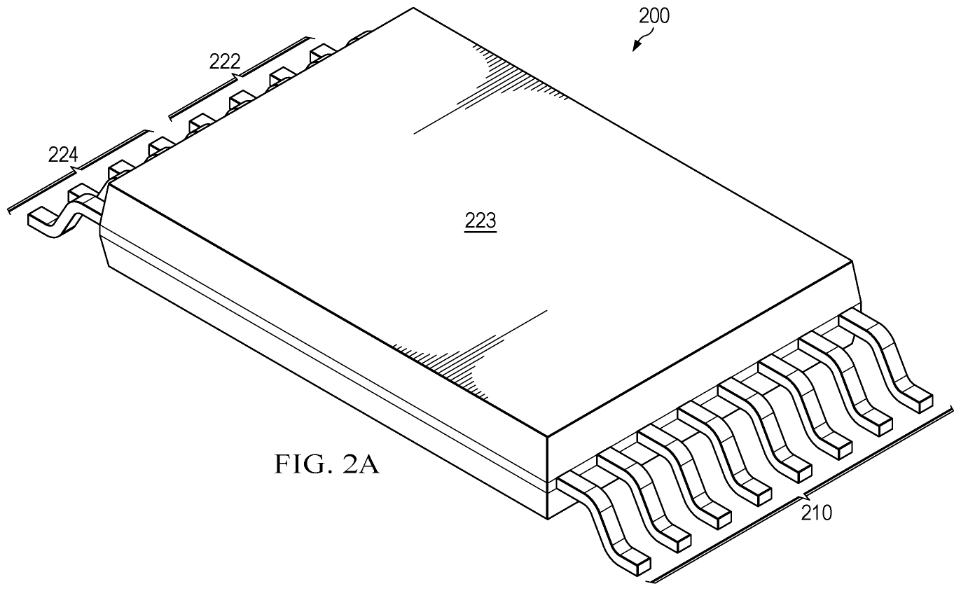

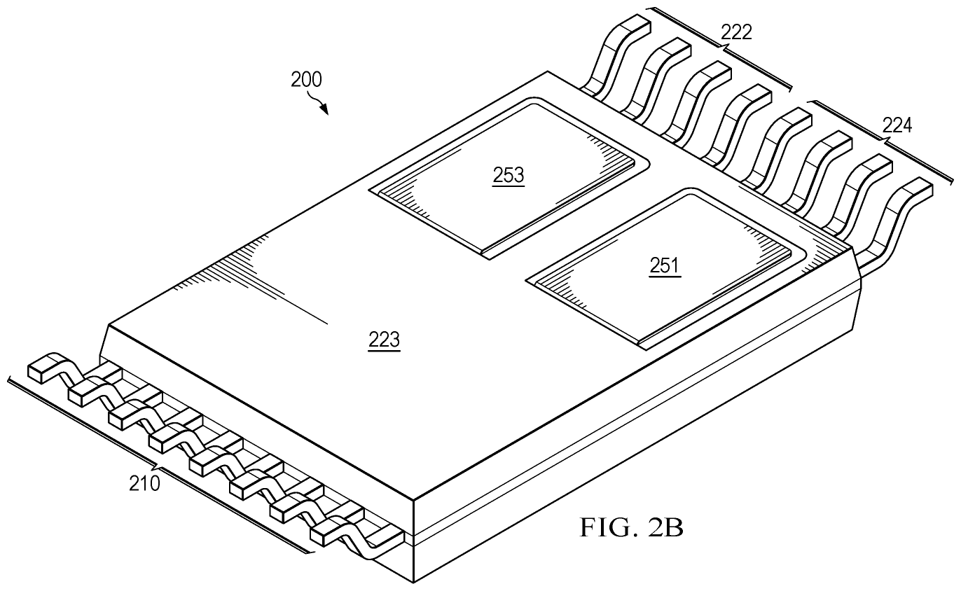

FIG. 2A illustrates, in a projection view from a top side, a semiconductor device package 200 that can be used in an example arrangement. The semiconductor device package 200 has mold compound 223 that forms the body of the semiconductor device package 200, a group of low voltage terminals 210, high voltage input terminals 222, and high voltage output terminals 224. In an example arrangement, the high voltage input terminals 222 are coupled together on a leadframe inside the mold compound 223, as is described further below, to form an input with low resistance. Similarly, the high voltage output terminals 224 are coupled together inside the mold compound 223, as is described further below, to form an output with low resistance. In FIG. 2, a sixteen-pin wide small outline integrated circuit (SOIC) package 200 is shown and the terminals 222, 224 and 210 are formed in “gull wing” shapes for use with a standard surface mount technology (“SMT”) footprint. Use of a standard pin out and a standard footprint semiconductor device package with the Hall elements of the arrangements reduces costs for mounting the devices to a system board or module (as compared to custom packages used in some prior approach Hall sensor solutions). In the arrangements, a standard footprint semiconductor device package can be used. Use of a “gull wing” terminal shape can provide some flexibility and allow some movement when the device is being mounted or during use, for example when the device heats during operation, increasing board level reliability (“BLR”). While the example semiconductor device package 200 shown in FIG. 2A is a leaded package that includes terminals 210, 222 and 224 that are external leads configured for surface mounting to a board using SMT, no-lead packages such as QFN packages can also be used. Other standard semiconductor package footprints such as dual in-line packages can be used.

FIG. 2B illustrates the semiconductor device package 200 shown in FIG. 2A, now illustrated from a bottom or board side view. In addition to the low voltage terminals 210, the high voltage input terminals 222 and high voltage output terminals 224, the semiconductor device package 200 includes thermal pads 251, 253 that are exposed from the mold compound 223. These thermal pads 251, 253 are formed by surfaces of an internal heat slug (not visible due to the mold compound 223) and provide direct thermal coupling to the internal heat slug for mounting to a corresponding thermal pad on a system board or module, enabling rapid heat dissipation from the semiconductor device package 200.

The semiconductor device packages of the example arrangements may be thicker than standard semiconductor device packages due to the use of an integral heat slug, as is explained below, but use of a standard footprint for the packages in some example arrangements enables assembly using standard tools and equipment. Use of the gull wing shape for the terminals with an “upset” leadframe, also further described below, can assist in keeping the overall thickness of the semiconductor device package small. Use of an upset leadframe can also enable an arrangement to be formed with a standard package thickness, as is described below.

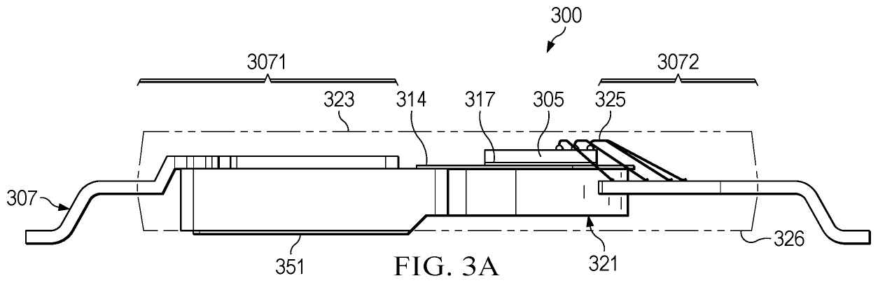

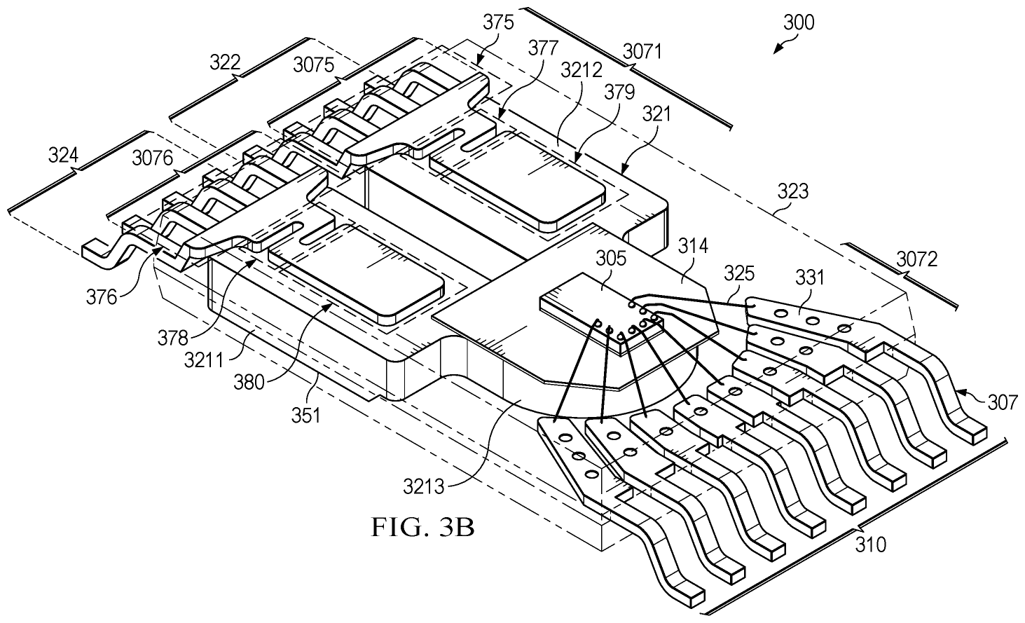

FIG. 3A illustrates, in a partial cross-sectional view, an example semiconductor device package 300 incorporating an arrangement. In FIG. 3A the semiconductor device package 300 is shown with the mold compound 323 that forms the body of the semiconductor device package shown transparent (as indicated by a dashed line) to allow visibility of the other elements. A leadframe 307 is used with terminals extending from inside the mold compound 323 to outside the mold compound 323. Leadframe 307 is an isolation leadframe that includes a high voltage section 3071 and a low voltage section 3072. An integral heat slug 321 is mounted to the board side of the high voltage section 3071 and can be formed of a thermal and electrical conductor such as a copper or copper alloy. The heat slug 321 is affixed to and electrically coupled to the high voltage section 3071 of the leadframe 307 and forms a low resistance current path to carry a current from an input portion to an output portion (see input and output signals IN+ and IN−, and current I in FIG. 1C) of the high voltage section 3071 of the leadframe 307, and the heat slug 321 has a connection portion shaped to carry the current to a position proximate to the semiconductor die 305. The current can be a high current of greater than an ampere and up to over 100 Amps. The heat slug 321 can also have an external thermal pad 351 that is exposed from the mold compound 323. Thermal pad 351 is arranged to transfer heat from the semiconductor device package 300 to a board or module thermal path to distribute the thermal energy from the semiconductor device package 300 during operations. In the example arrangements, a second thermal pad (not visible in FIG. 3A, see similar thermal pads 251, 253 in FIG. 2B) is also formed by the integral heat slug 321 and exposed from the mold compound 323.

The semiconductor device package 300 includes semiconductor die 305 mounted in a “face up” orientation with the bond pads and a device side surface facing away from a board side surface 326 of the semiconductor device package 300. The semiconductor die 305 includes a Hall element (not visible in FIG. 3A) or more than one Hall element that is/are placed proximate to the heat slug 321, so that a magnetic field corresponding to the current flowing through the heat slug 321 can be sensed by the Hall element(s) within the semiconductor die 305 (see Hall elements 1081, 1082 in FIG. 1C). However, the semiconductor die 305 is electrically isolated from the heat slug 321 and the high voltage section 3071 of the leadframe 307. Spacing and materials are used to achieve galvanic isolation between the semiconductor die 305 and the high voltage section 3071 of the leadframe 307, and also between the semiconductor die 305 and the integral heat slug 321.

An electrically insulating material 314 such as a polyimide, such as a polyimide film, or a laminate, such as a bismaleimide triazine (BT) resin laminate or a glass-reinforced fire-retardant epoxy (FR4) laminate, is used to provide electrical isolation between the backside surface of the semiconductor die 305 and the heat slug 321. Other dielectric materials can be used. In an example a Kapton® film can be used for the insulating material 314. The insulating material 314 provides a die mount area for the semiconductor die 305. A non-conductive die attach material 317, which can be a die attach film, tape or can be a paste or a liquid that is subsequently cured, is used to mount the semiconductor die 305 to the insulating material 314. Electrical connections such as wire bonds or ribbon bonds, here wire bonds 325 are shown, connect bond pads (not shown, but see, for example bond pads 102 in FIG. 1B) on the semiconductor die 305 to interior leads of the low voltage section 3072 of the leadframe 307.

FIG. 3B is a projection view of the semiconductor device package 300 that is shown in the cross-section of FIG. 3A, and provides some additional details. In FIG. 3B, the high voltage section 3071 of the leadframe 307 is shown with an input portion 3075 and an output portion 3076. The input portion 3075 of the high voltage section 3071 of the lead frame overlies and is coupled to an input portion 3212 of the heat slug 321. The output portion 3076 of the high voltage section 3071 of the leadframe 307 overlies and is coupled to an output portion 3211 of the heat slug 321. The input portion 3075 and the output portion 3076 of the high voltage section 3071 of the leadframe 307 have interior lead portions 375, 376 that extend through the mold compound 323 and terminals 322, 324 are formed from exterior lead portions (exterior to the mold compound 323). The input portion 3075 and the output portion 3076 of the high voltage section 3071 of the leadframe 307 also have mount portions 379, 380. The respective mount portions 379, 380 are attached to a top surface of the integral heat slug 321 in corresponding input portion 3212 and output portion 3211. In an example when a copper leadframe is used for leadframe 307 and a copper heat slug is used for the integral heat slug 321, these parts can be brazed, welded or soldered together to be mechanically attached and electrically coupled at mount portion 379 of the input portion 3075 and mount portion 380 for the output portion 3076 to form a copper-to-copper bond. The input portion 3075 and the output portion 3076 of the leadframe 307 also have flexible connect portions 377, 378. The flexible connect portions 377, 378 overlie the heat slug 321 and connect the interior lead portions 375, 376 to the mount portions 379, 380. However, the flexible connect portions 377, 378 are not brazed or welded to the heat slug 321. When the integral heat slug 321 is displaced during processing, for example during molding, the flexible connect portions 377, 378 allow the mount portions 379, 380 to move with the heat slug 321, while the interior lead portions 375 and 376 remain in place and remain properly aligned. In an example, during a transfer molding operation, the heat slug 321 can be displaced by pressure from a liquid mold compound being forced into a mold and pressing on the heat slug 321. The flexible connect portions 377, 378 of the leadframe 307 can move so that the mount portions 379, 380 move with the heat slug 321. The interior lead portions 375, 376 are held by a clamping action at a mold boundary during molding, so by use of the arrangements the interior lead portions 375, 376 remain in place even when the heat slug 321 moves. This flexible connect feature of the arrangements prevents the displacement of the heat slug 321 from causing misalignment of the leads of the leadframe 307. The use of the arrangements can also reduce or eliminate mold compound cracking or delamination defects during production when the heat slug 321 moves relative to the other elements. In simulations comparing the packaged semiconductor device including the flexible connect feature of the arrangements to prior approaches formed without the use of the arrangements, the use of the flexible connect features reduced or eliminated stress on the interior lead portions of the leadframe during molding, which remained in position when the heat slug was displaced.

The insulating layer 314 is shown placed over a heat slug connect portion 3213 of the heat slug 321. Heat slug connect portion 3213 connects the input portion 3212 and the output portion 3211 and is shaped to carry a current proximate to the Hall elements (not shown) in the semiconductor die 305. Magnetic shields can be placed over the Hall elements, or magnetic concentrators can be placed of the Hall elements, to improve performance (not shown for clarity of illustration). Magnetic shields for Hall sensor semiconductor dies are disclosed in the co-owned U.S. patent application Ser. No. 18/499,086, filed Oct. 31, 2023, which is hereby is hereby incorporated herein by reference in its entirety.

Returning to FIG. 3B, wire bonds 325 connect bond pads (see bond pads 102 in FIG. 1B, for example) on the semiconductor die 305 to the low voltage section 3072 of the leadframe 307, the wire bonds 325 are attached to leads of interior lead portion 331 of the low voltage section 3072. Mold compound 323 covers the semiconductor die 305, the wire bonds 325 and the heat slug 321, with the thermal pad 351 on the board side surface of the heat slug 321 exposed from the mold compound 323. The interior leads 331 are coupled to exterior leads to form terminals 310 that extend beyond mold compound 323.

As shown in FIG. 3B, the flexible connect portions 377, 378 in the illustrated example are “S” shaped from a plan view, however, other shapes can be used to form additional alternative arrangements, such as “Z” shapes, “T” shapes, or “V” shapes, which also permit motion of the leadframe mount portions 379, 380 while flexibly moving with the heat slug 321.

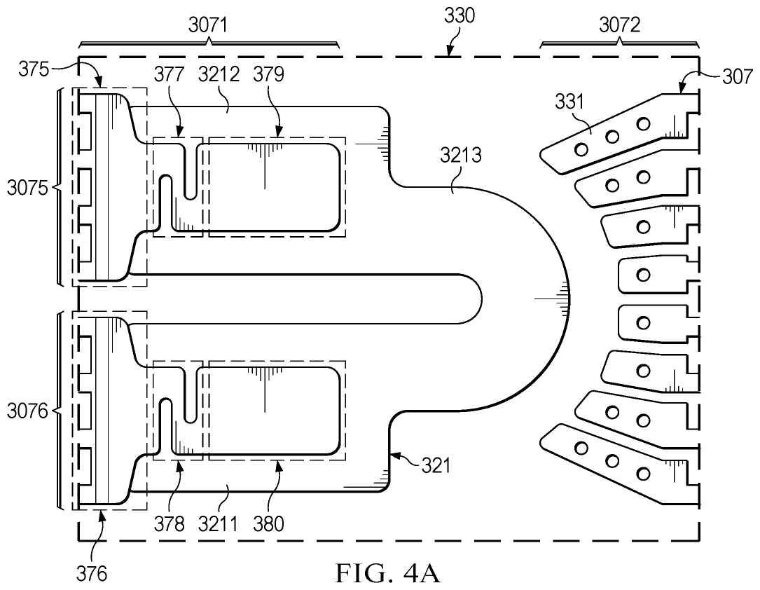

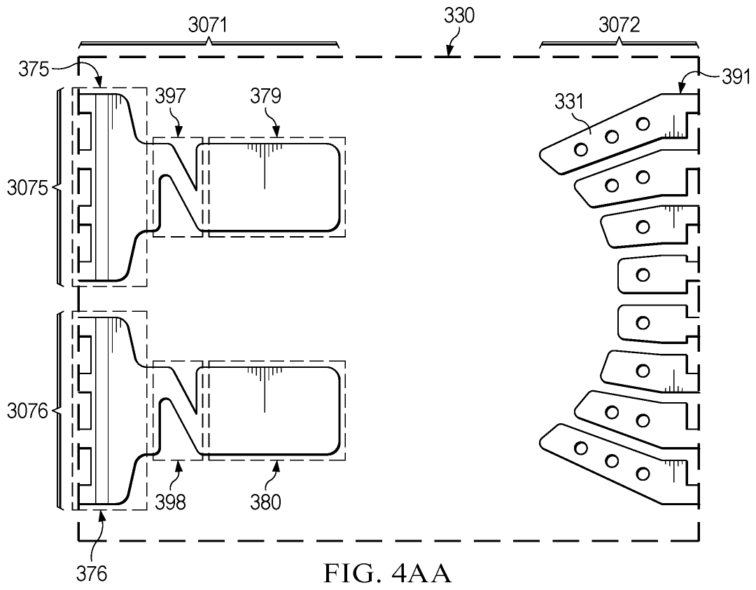

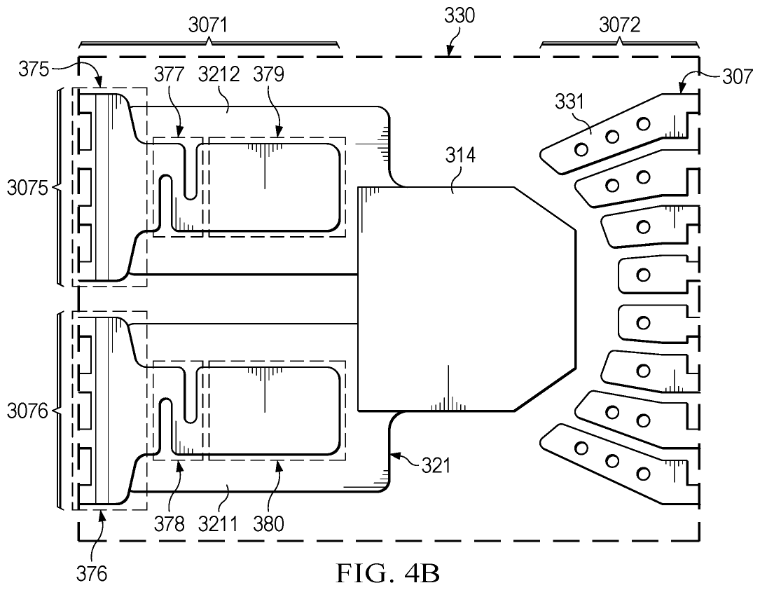

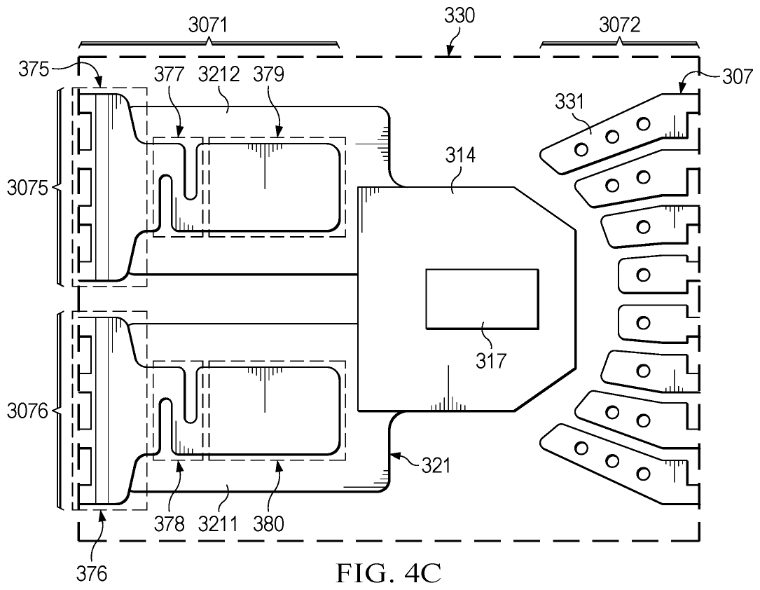

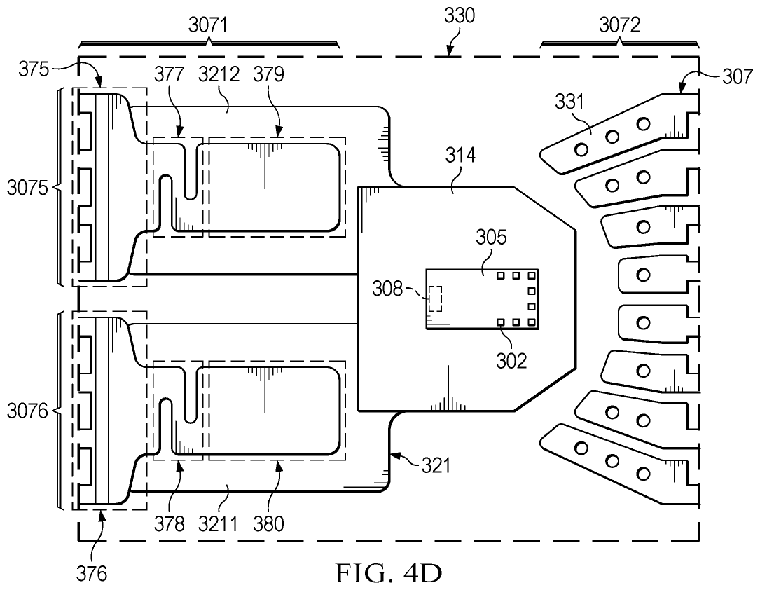

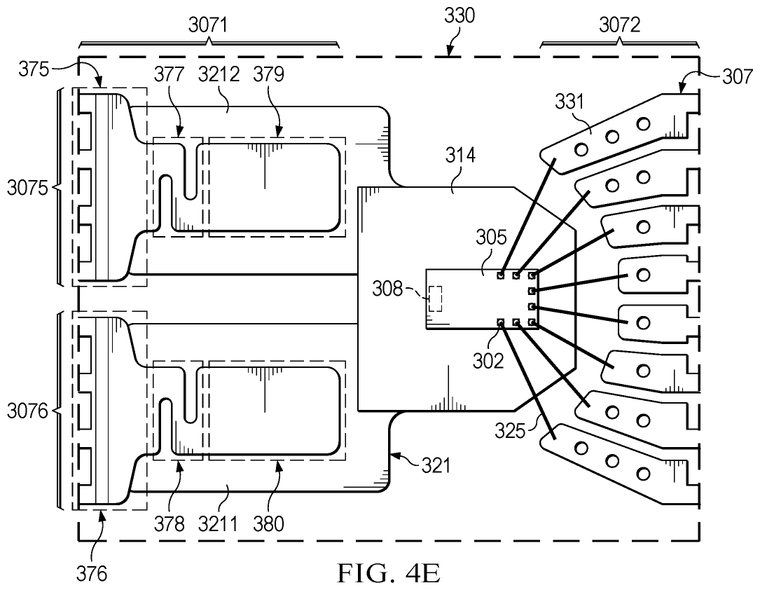

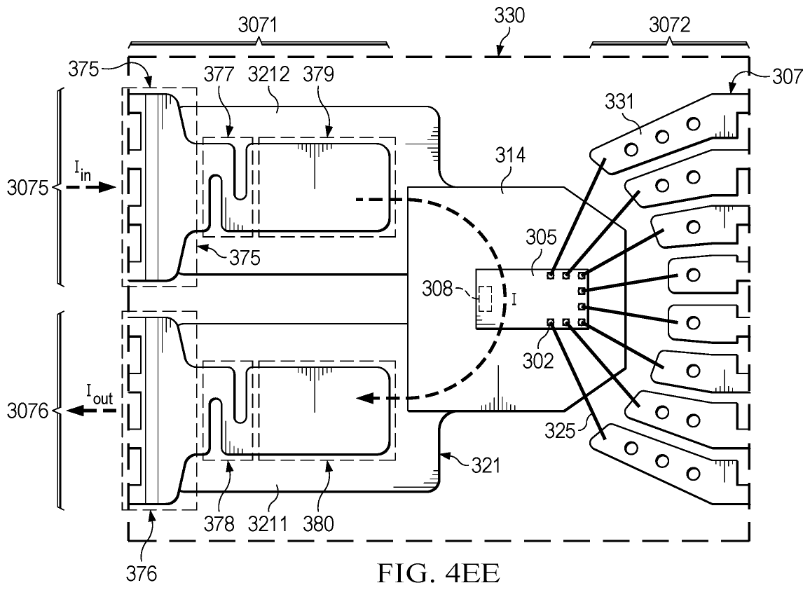

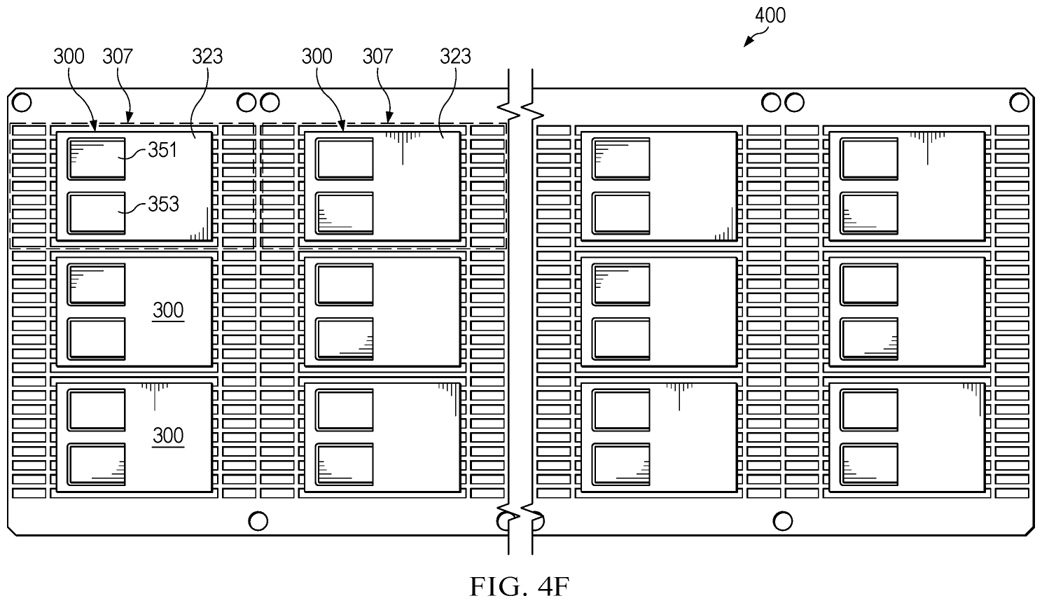

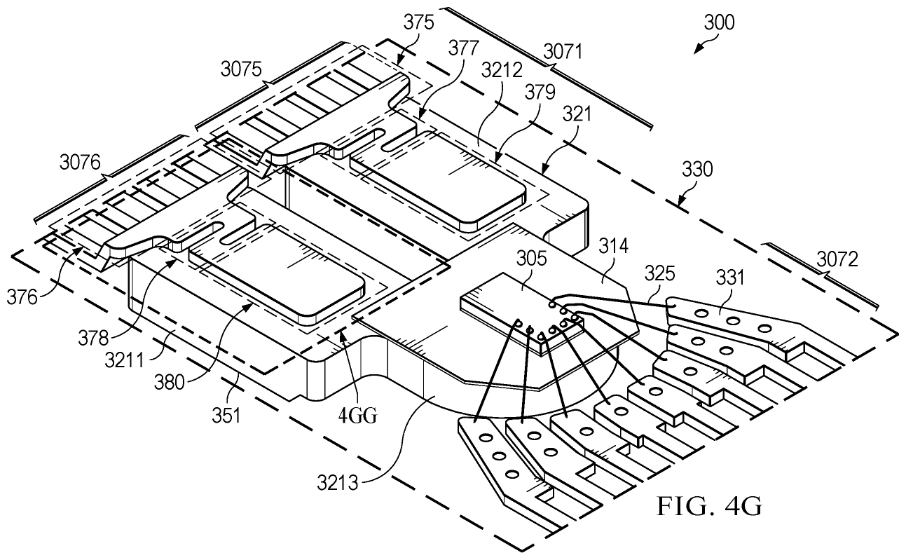

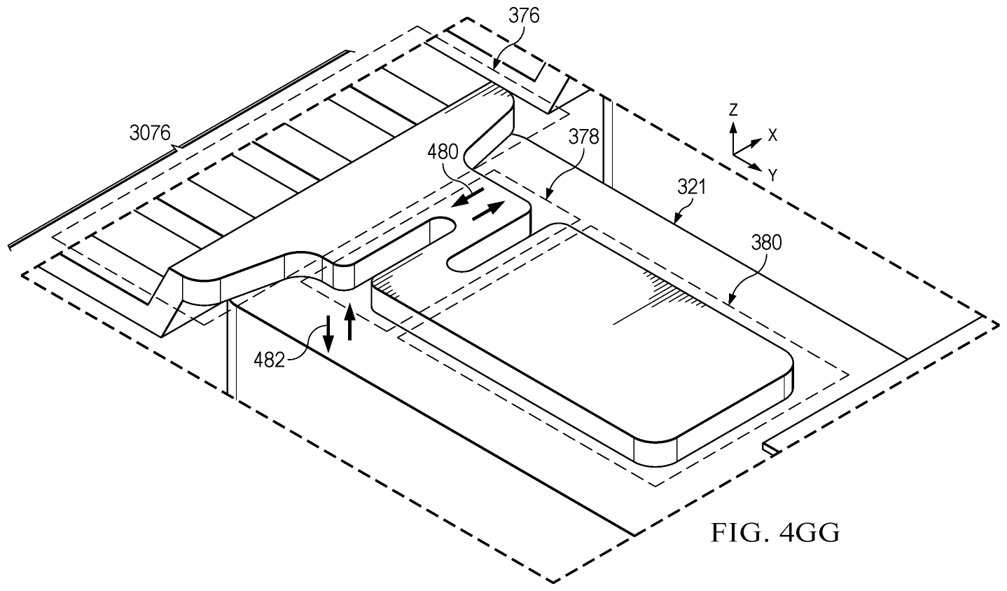

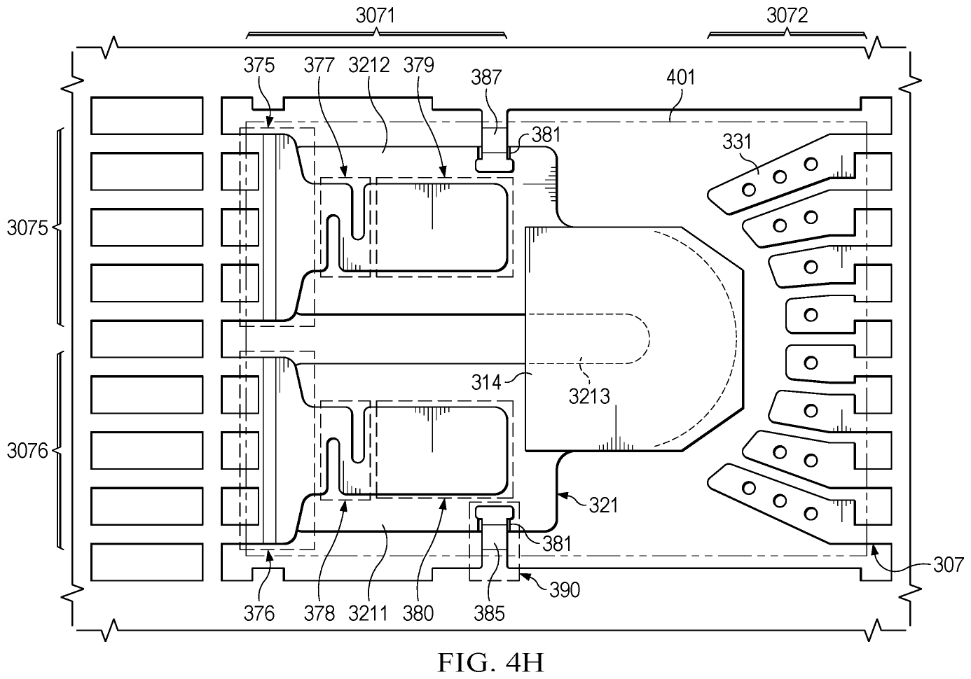

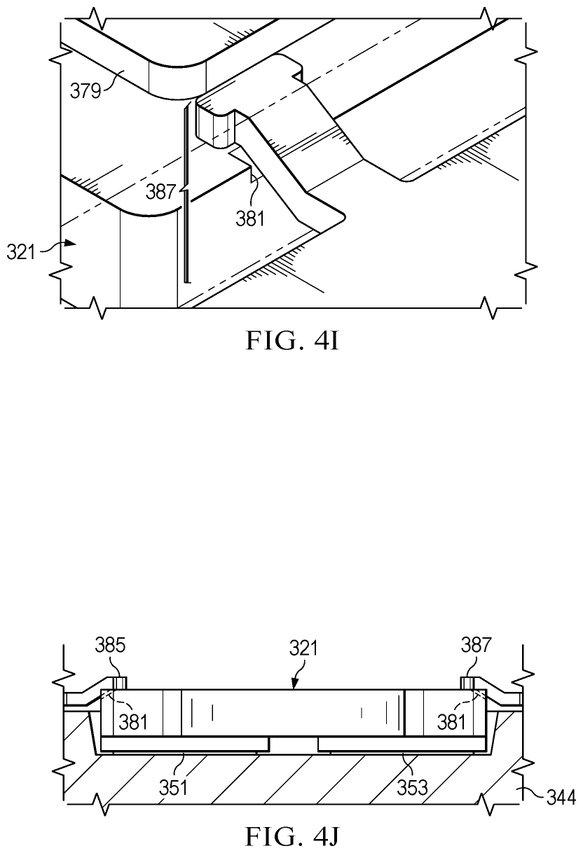

FIGS. 4A, 4AA, 4B-4D and FIGS. 4E-4EE illustrate, in a series of plan views and side views, selected steps for forming a semiconductor device package of an example arrangement. FIG. 4F illustrates, in a plan view, a leadframe array including molded semiconductor device packages of an arrangement arranged in rows and columns. FIGS. 4G-4GG illustrate, in a projection view and a corresponding close-up view, further details of the example arrangement of FIGS. 4A-4D. FIG. 4H illustrates, in a plan view, portions of an alternative example arrangement. FIG. 4I illustrates, in a close-up projection view, details of the alternative example arrangement of FIG. 4H. FIG. 4J illustrates an end view of a portion of the alternative example arrangement of FIG. 4H in a mold tool used in a molding process.

In FIG. 4A, a plan view of a portion of leadframe 307 illustrates the example arrangement of FIGS. 3A-3B at a beginning assembly step. The dashed line 330 indicates that FIG. 4A is a partial view of the leadframe 307. Heat slug 321 is shown with input portion 3212 and output portion 3211 that are connected by heat slug connect portion 3213. The leadframe 307 includes high voltage section 3071 mounted to the heat slug 321, with high voltage section 3071 and low voltage section 3072 spaced apart. During processing, the leadframe 307 has temporary support portions (not shown in FIG. 4A) that tie the exterior leads and the various portions together for mechanical support during processing. The temporary support portions can include tie bars and dam bars that are placed outside the area where molded semiconductor devices are to be formed, and after molding, these temporary supports are trimmed away, freeing the exterior leads (not shown in FIG. 4A) and isolating them from one another. In FIG. 4A, high voltage section 3071 of leadframe 307 has the high voltage input portion 3075 mounted to the input portion 3212 of the heat slug 321, and high voltage output portion 3076 mounted to the output portion 3211 of the heat slug 321. In the low voltage section 3072 of the leadframe 307, leads of the interior lead portion 331 are shown arranged for wire bond connections. The leads of interior lead portion 331 will extend to a mold compound bonding area at the package boundary where the mold compound will bond to the leads, and exterior leads (not shown) extending from the leads of interior lead portion 331 through the package boundary and outside the mold compound will be shaped to form terminals, similar to terminals 210 in FIGS. 2A-2B. In FIG. 4A the plan view is from a top side of the heat slug 321, with the leadframe 307 placed over the heat slug 321.

The high voltage section 3071 of the leadframe 307 includes the input portion 3075 and output portion 3076. The input portion 3075 includes interior lead portion 375 and mount portion 379. The mount portion 379 is fixed to the surface of the input portion 3212 of the heat slug 321. A flexible connect portion 377 connects the interior lead portion 375 to the mount portion 379. The flexible connect portion 377 is not fixed to the heat slug, unlike the mount portion 379. The flexible connect portion 377 is shaped to move and allow the interior lead portion 375 to remain in a fixed position if the heat slug 321 moves. The flexible connect portion 377 moveably connects the mount portion 379 to the interior lead portion 375, meaning that the flexible connect portion 377 can move while maintaining the connection between the interior lead portion 375 and the mount portion 379. The shape of the flexible connect portion 377 may be an “S” shape as shown in FIG. 4A, alternatively the flexible connect portion 377 may have other shapes, such as “Z” shapes, “T” shapes, “L” shapes, or “V” shapes, as seen in the plan view. (See FIG. 4AA, where an alternative “Z” shape is illustrated). While the flexible connect portion 377 lies over and may contact the surface of the heat slug 321, the flexible connect portion 377 is not fixed to the heat slug 321 so that it can move, while the interior lead portion 375 is not moved. In a transfer mold operation used to form a semiconductor device package, the leads of interior lead portion 375 will be clamped at the mold boundary (the interior leads will extend outside the package body to form exterior leads outside the mold compound) and during molding, if the heat slug 321 is displaced laterally or vertically, the flexible connect portion 377 allows the mount portion 379 that is welded or brazed or otherwise fixed to the heat slug 321 to move with the heat slug 321 without dislocating the interior lead portion 375, which decreases defects during packaging and reduces mold compound delamination issues during and after production.

Referring again to FIG. 4A, the output portion 3076 of the high voltage section 3071 of leadframe 307 has another interior lead portion 376, another flexible connect portion 378, and another mount portion 380 that correspond to and operate similarly to the interior lead portion 375, the flexible connect portion 377 and mounting portion 379.

As mentioned previously, while the heat slug 321 has a connect portion 3213 shown in a “C” or “U” shape in the illustrated examples, other shapes can be used for the connect portion 3213 for heat slug 321. The heat slug 321 provides a low resistance path to carry current from the input portion 3075 of the high voltage section 3071 through the heat slug 321 (see current I in FIG. 1C, for example). In an example assembly process, the leadframe 307 is provided in a strip, grid or array having multiple unit leadframes that are temporarily connected together by tie bars formed of the leadframe material, and supporting the leads during assembly (see array 400 in FIG. 4F.) Multiple packaged semiconductor devices are formed simultaneously to increase throughput, and reduce costs. The completed semiconductor device packages are then cut apart to form individual semiconductor device packages.

The leadframe 307 and the heat slug 321 of FIG. 4A can be provided assembled together by a leadframe vendor as a sub-assembly, ready for additional processing steps at a device packaging facility. Alternatively, the leadframe 307 can be provided in a strip or matrix, and the integral heat slug 321 can be mounted to the leadframe 307 in an assembly step prior to the other steps for packaging that are further described below. In an example, the leadframe 307 is copper or copper alloy, and the heat slug 321 is also copper or copper alloy, so that the attachment of the mount portions can be a copper-to-copper weld or braze that is reliable and has no thermal mismatch issues. Soldering can be used to fix the mount portions of the leadframe 307 to the heat slug 321. Alternate materials that can be used for the leadframe include steel, stainless steel, Alloy 42, and other conductors used for leadframes.

The interior lead portions 331, 375, 376 of leadframe 307 in FIG. 4A also show another optional feature, in FIG. 4A the leadframe 307 has “upset” leads in the high voltage portion 3071. By having a step upwards away from the board side surface, the leadframe 307 can be positioned over a heat slug 321 that is thicker than half of the thickness of the molded package, allowing the total thickness of the molded package to be kept relatively thin. The interior lead portions 331, 375, 376 extend to and through the center of a mold, so the leads exit the molded package being formed at the middle of the molded package, when viewed from a side view. If, instead of an upset leadframe, the leadframe 307 was a flat planar sheet, the total package thickness would need to be increased to accommodate the total thickness of the heat slug 321 which would then lie in half of the molded package body below the planar leadframe. Use of the upset leadframe 307 helps maintain a total package thickness similar to existing SOIC packages, which can be an advantage in board assembly.

FIG. 4AA illustrates the leadframe 307 in an alternative arrangement. In FIG. 4AA, a plan view shows flexible connect portions 397, 398 that are “Z” shapes, in contrast to the “S” shapes shown in FIG. 4A, to show that various shapes can be used to form the flexible connect portions of the leadframe 307. The flexible connect portions 397, 398 are moveable, so that when the mounts 379, 380 are attached to an integral heat slug (see, for example, heat slug 321 in FIG. 4A), the Z shaped flexible connect portions 397, 398 allow the interior lead portions 375, 376 to remain in place while the integral heat slug is displaced in a molding operation.

FIG. 4B illustrates the elements of FIG. 4A after an additional processing step. In FIG. 4B, insulating material 314 is shown mounted on the top side surface of the heat slug 321. As positioned in the example shown in FIG. 4B, the insulating material 314 is placed over the heat slug 321 and over the connect portion 3213 (obscured in FIG. 4B, see 3213 in FIG. 4A). The insulating material 314 provides an electrically isolated die mounting area for a semiconductor die to be mounted, while the semiconductor die will be isolated from the leadframe 307 and the heat slug 321. The insulating material 314 can be, for example, a polyimide material. In one example useful with the arrangements, a Kapton® tape or film, or another polyimide tape or film, can be used for insulating material 314. Other materials that can be used include dielectric laminate materials, insulating substrate materials such as FR4 and BT resin, and ceramic materials.

FIG. 4C illustrates the elements of FIG. 4B after an additional processing step. In FIG. 4C, a die attach material 317 is shown applied to the insulating material 314. The die attach material 317 can be a non-conducting die attach film (“NCDAF”). Epoxy or pastes used as non-conductive die attach materials can be used.

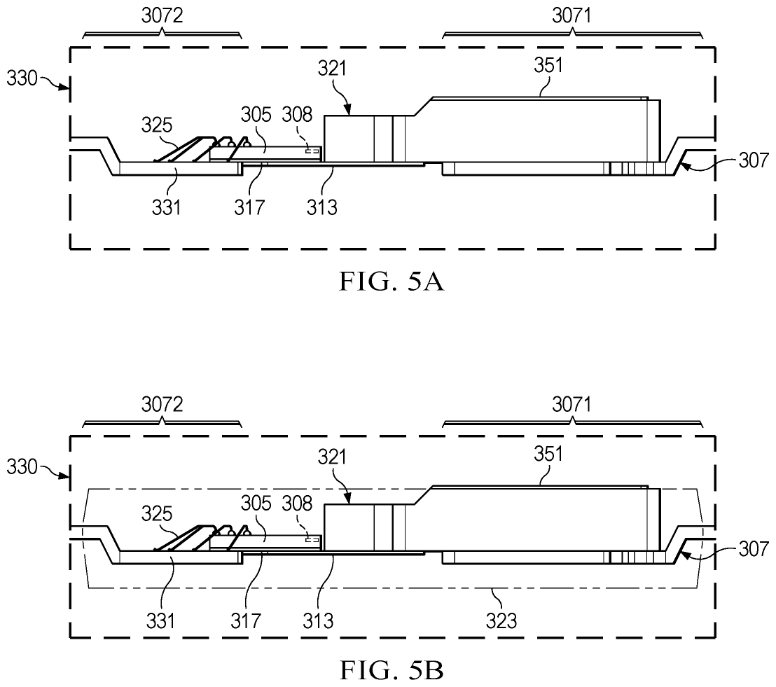

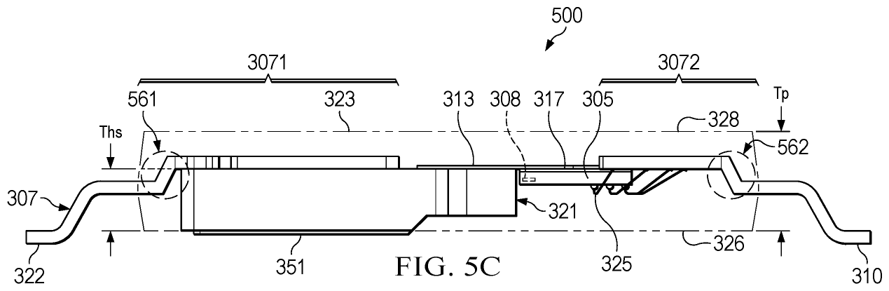

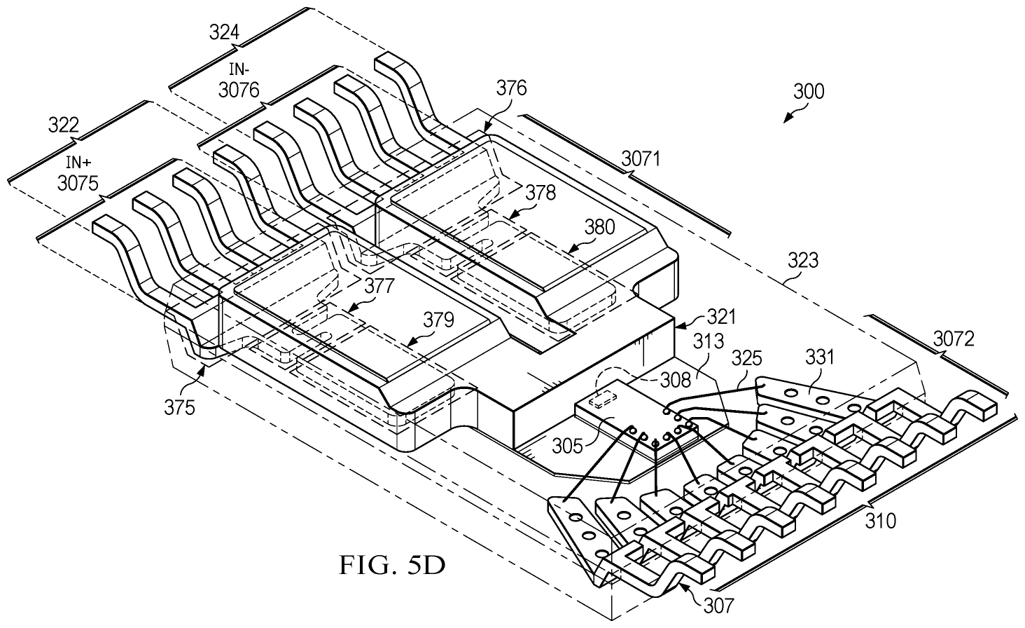

FIG. 4D illustrates the elements of FIG. 4C after an additional processing step. In FIG. 4D a semiconductor die 305 is shown mounted to the insulating material 314, using the die attach material shown in FIG. 4C (see 317 in FIG. 4C, the die attach material is not visible in FIG. 4D as it lies beneath the semiconductor die 305). Pick and place tools can be used to place the semiconductor die 305 on the die attach material. The semiconductor die 305 includes at least one sensor, in the example arrangements shown a Hall element 308 is used. Alternative arrangements include two or more Hall elements (see Hall elements 1081, 1082 in FIG. 1C, for example) The Hall element 308 is positioned proximate to the connect portion 3213 of heat slug 321, to ensure the Hall element is exposed to a magnetic field that will occur due to a current flowing through heat slug 321. In the example shown in FIG. 4D, the Hall element is overlying the heat slug 321. The semiconductor die 305 also has bond pads 302 formed on a device side surface, which in this example, is facing away from the board side surface of the heat slug 321 and away from the board side surface of the leadframe 307. In additional alternative arrangements, the semiconductor die 305 may be mounted facing towards the board side surface of the heat slug 321, with the bond pads facing the board side surface, and with the semiconductor die attached to a board side surface of an insulating material. (See, for example, the alternative arrangement of FIGS. 5A-5D and the corresponding descriptions below.)

FIG. 4E illustrates, in another plan view, the elements of FIG. 4D after additional processing. In FIG. 4E, wire bond connections 325 are shown between the bond pads 302 on the semiconductor die 305 and the interior lead portions 331 of the low voltage section 3072 of the leadframe 307. The wire bonds 325 provide electrical connection to interior leads 331 that will extend from the molded package body to exterior leads that form terminals for a packaged device. (See, for example, terminals 210, 222 and 224 in FIGS. 2A-2B, terminals 310 in FIG. 3B). Semiconductor die 305 can operate at and be connected to lower voltage signals (lower than the high voltages at the high voltage portion 3071, for example), enabling the semiconductor die 305 to be fabricated in a conventional semiconductor manufacturing facility. The Hall element 308 allows sensing of a current much higher than can be safely carried by the devices in semiconductor die 305 (in the range or tens or even a hundred amps, for example) and at high voltages much greater than can be safely applied to semiconductor die 305 (tens or hundreds of Volts, for example) because the Hall element senses the magnetic field caused by the current flowing through the heat slug 321 while the semiconductor die 305 and the low voltage section 3072 of the leadframe 307 are electrically isolated from the current and the high voltages applied to the high voltage inputs and outputs. In FIG. 4E, wire bonds 325 are shown coupling the bond pads 302 to the leads of the interior lead portion 331.

In an example wire bonding process useful in forming the arrangements, a wire bonding tool includes a capillary and a supply of bond wire. The capillary is made of a material that can withstand mechanical pressure, such as a ceramic material. The bond wire has a free end that extends through an opening in the capillary. To begin a bonding cycle, a flame or electronic arc is applied to the end of the bond wire to form a molten ball, sometimes referred to as a “free air ball.” The capillary is positioned (or the semiconductor die is moved relative to the capillary) so that the capillary is above a bond pad to be bonded to. The capillary moves the free air ball to physically contact the bond pad, and a combination of thermal energy (the elements are heated during bonding), ultrasonic vibration (applied to the capillary) and mechanical pressure are applied to cause the molten ball to bond to the bond pad, and a “ball bond” is formed. The capillary then moves away from the bond pad while allowing the bond wire to extend through the opening in the capillary. Using clamps and a controlled motion, the bond wire can be shaped in an arc above the edge of the semiconductor die and carry the bond wire to a position above a leadframe lead to be bonded to. The capillary then uses mechanical pressure and ultrasonic energy to form a “stitch” bond on the conductive lead. The capillary moves a short distance from the stitch bond and breaks or cuts the bond wire to complete a wire bond between the bond pad and the lead. A new free air ball is formed and the bonding cycle begins over a new bond pad.

This “ball and stitch” bonding cycle has long been used in industry, is fully automated and is fairly rapid, several wire bonds 325 can be formed per second and the wire bonding tool can rapidly form the wire bonds needed for each semiconductor die that is mounted on a leadframe strip or array. The wire bonds can be formed from bond wire of copper, palladium coated copper (PCC), silver, aluminum or gold. When copper or PCC bond wires are used, an anoxic atmosphere is often established within the wire bonding tool to reduce oxidation of the copper wires, which is accelerated by the elevated temperatures used in wire bonding. Nitrogen can be used to form the anoxic environment.

FIG. 4EE illustrates the elements of FIG. 4E in another plan view, and in addition, shows the path a current “I” applied to the input portion 3075 of the leadframe 307 takes through the heat slug 321 and out again at the output portion 3076 of the leadframe 307. The current “Iᵢₙ” enters at the exterior terminals (not shown) coupled to the interior lead portions 375 of the input portion 3075 of the high voltage section 3071 of leadframe 307. The current “I” flows through the flexible connect portion 377 and to the mount portion 379 of the leadframe 307 and is coupled to the input portion 3212 of the heat slug 321. The current “I” flows through the connect portion of the heat slug 321 (the connect portion is not visible in FIG. 4EE, it is beneath the insulating layer 314, see the connect portion 3213 in FIG. 4A) and flows proximate to the Hall element 308 on semiconductor die 305. The current “Iout” flows into the output portion 3211 of the heat slug 321 and is coupled to the output portion 3076 of the high voltage section 3071 of the leadframe 307 by the mount portion 380. The current “I” thus flows through the flexible connect portion 378 and to the interior lead portion 376, where it is coupled out of the package to exterior terminals (not shown, but see terminals 224 in FIGS. 2A-2B, for example). (Note that the heat slug 321 and the high voltage portion 3071 of the leadframe 307 form a conductive path, so the current “I” could be applied to either the input or output portion 3075, 3076, that is the labels “input portion” and “output portion” used in this description are arbitrary and can be reversed.)

After the processes described above and shown in FIGS. 4A-4E, a molding step forms the mold compound 323 (see 323 in FIGS. 3A-3B) to complete the packaged semiconductor device 300. In an example, a transfer mold tool with unit mold shapes is used. In an example molding process, a solid or powdered thermoset epoxy mold compound (“EMC”) of thermoset epoxy resin can be used. The solid EMC can include fillers to increase strength and enhance thermal transfer of the molded package. A leadframe strip or array is placed in a mold. The leadframe strip can have tens or hundreds of semiconductors dies mounted to unit leadframe portions. As shown in FIG. 4E, at this stage the semiconductor dies have been wire bonded to form the wire bond connections. The mold tool is then closed so that the semiconductor dies are surrounded by the molds. The solid mold compound is heated to a liquid state. A hydraulic ram forces the liquid mold compound through runners and into the molds. During transfer molding the flowing liquid mold compound can displace the heat slug, which is positioned for example in the bottom half of a unit mold and supported by the leadframe. The mold compound fills the molds and encapsulates the semiconductor dies, the bond wires, the heat slugs, and portions of the leadframes, with exterior portions of the leads extending from the molds. The mold compound cures and forms semiconductor device packages that are still connected by the leads.

FIG. 4F illustrates, in a plan view from a board side, molded semiconductor devices 300 shown on a leadframe array 400 having unit leadframes 307 arranged in rows and columns. The leadframe array 400 is shown after the completion of the molding step described above. Each semiconductor device package 300 has exterior leads that will be shaped in a subsequent step to form terminals (see for example terminals 222, 224 and 210 in FIGS. 2A, 2B, and terminals 310, 322, 324 in FIG. 3B) after a singulation, trim and form (“STF”) tool cuts apart the molded devices and removes tie bar supports formed of the leadframe material that provide mechanical support during the previous process steps. Mold flash, that is excess mold compound that may lie between packages and between leads, will be removed from the packaged devices. Each semiconductor device package 300 has exposed thermal pads 351, 353 corresponding to the input portion and the output portion of the heat slugs (see, for example, thermal pad 351 shown in FIGS. 3A and 3B). The use of an array or strip of unit leadframes 400 to form the packaged semiconductor devices 300 allows for increased throughput as the die attach, die mount, wire bonding, and molding steps described above can be formed for multiple packaged semiconductor devices in parallel, reducing costs and reducing time needed to produce the semiconductor device packages.

FIGS. 4G-4GG illustrate, in a projection and in a close-up view, respectively, the flexible connect portion of the leadframe and a heat slug of an example arrangement, to further describe the features. In FIG. 4G, the elements of the plan view of FIG. 4B are again shown, now in a projection view, with heat slug 321, the leadframe 307, which has a low voltage section 3072 with interior lead portion 331, and the high voltage section 3071. The high voltage section 3071 includes an input portion 3075, and an output portion 3076. The input portion 3075 has interior lead portion 375, a flexible connect portion 377, and a mount portion 379. The output portion 3076 similarly has another interior lead portion 376, another flexible connect portion 378, and another mount portion 380. The flexible connect portions 378, 379 overlie but are not attached to the heat slug 321, while the mount portions 379 and 380 are affixed to the heat slug 321 to provide physical attachment and electrical coupling to the heat slug 321. The interior lead portions 375, 376 are coupled to the mount portions 379, 380 by the flexible connect portions 377, 378, and overlie but are not attached to the heat slug 321. It is noted that the interior lead portions 376, 375 and the flexible connect portions 378, 377 may contact the heat slug 321, but are not fixed to it, and can move independently of the heat slug 321 during molding.

The dashed line 330 in FIG. 4G again indicates that the view of the leadframe 307 is a partial view. The interior lead portions 375, 376 and 331 will extend outside line 330 and form exterior leads that will be shaped into terminals (see terminals 222, 224 and 210 in FIGS. 2A-2B, and terminals 310, 322 and 324 in FIG. 3B, for example).

FIG. 4GG illustrates, in a close-up view, the portion of FIG. 4G indicated by the dashed circle labeled “4GG.” In FIG. 4GG, a portion of the heat slug 321 and a portion of the high voltage output portion 3076 are shown. Interior lead portion 376 and flexible connect portion 378 are shown in FIG. 4GG. The pair of arrows labeled 480 indicate the possible movement of the flexible connect portion 378 in the X-Y plane (see labels “X” and “Y” in FIG. 4GG), that is if the heat slug 321 is moved, for example during molding, the flexible connect portion 378 can also move, and can move without causing the interior lead portion 376 to move. Similarly, the pair of arrows labeled 482 indicate that the flexible connect portion 378 can move in the Z direction (see label “Z” in FIG. 4GG), that is vertically (as the elements are oriented in FIG. 4GG) if the heat slug 321 moves, and the flexible connect portion 378 can move without causing the interior lead portion 376 to move. The use of the arrangements improves the reliability of the semiconductor device package (see 300 in FIG. 3A) by reducing or eliminating delamination failures and stress cracking of the mold compound, and by keeping the leads of interior lead portion 376 in alignment during transfer molding, even if the heat slug 321 is displaced during molding.

FIG. 4H illustrates the elements of FIG. 4G in another plan view and illustrates an additional optional feature that can be used in an additional arrangement. In FIG. 4H, the leadframe 307 is shown in a plan view with the heat slug 321 mounted to the mount portions 379, 380 prior to mounting a semiconductor die. The insulating material 314 is shown overlying the heat slug in the interconnect portion. In FIG. 4H, a line 401 shows the boundary of the molded package that will be formed in a later step. Struts 387 and 385 are shown that are part of the leadframe 307 and which extend from support bars of the leadframe and which overlie and contact the heat slug 321. In a transfer molding operation, the struts 385 and 387 help to ensure that the board side surface of the heat slug 321 remains properly positioned at the bottom of a mold chase, so that mold compound does not cover the thermal pads at the board side surface. The struts 385, 387 are shaped to engage and contact the heat slug 321 and when the leadframe 307 is placed in a mold of a transfer mold tool, act as clamps to retain the heat slug 321 during the molding process so that the heat slug 321 cannot “float” upwards and allow the mold compound to flow between the thermal pads and the bottom of the mold chase, reducing or eliminating the possibility that the thermal pads may be partially covered with mold compound in the finished device packages. In FIG. 4H, the heat slug 321 has a slot 381 on the side arranged to receive the strut and contact the strut 387. It is noted that the struts 385, 387 can also be used independently of the flexible connect portions 377, 378 to position an integral heat slug in a molded semiconductor device package, although the struts can also be combined with the flexible connect portions as shown in FIG. 4H. An alternative arrangement would have the struts 385 387 without the flexible connect portions 377, 378.

FIG. 4I illustrates, in a close-up view, the strut 387 of FIG. 4H. The strut 387 is shaped as an “upset” leadframe feature that rises above the plane formed by the leadframe 307. When the leadframe 307 is mounted to the heat slug 321, the strut 387 engages with a slot 381 in the heat slug 321, and overlies a portion of the top surface of the heat slug 321. Strut 385 (see FIG. 4H) is similarly shaped. The struts 385, 387 in FIG. 4H provide stability for the heat slug 321 during molding.

FIG. 4J illustrates the heat slug 321 and the struts 385, 387 in and end view while the elements are positioned in a mold 344 for a transfer mold tool. The thermal pads 351, 353 of the heat slug 321 are shown contacting the surface of the mold 344 and the struts 385, 387 are shown engaging with a slot (see 381) formed in the sides of the heat slug 321 at the top surface of the heat slug 321. During a molding operation when liquid mold compound flows into the mold 344, the struts 385 and 387 act as clamps, holding the heat slug 321 in place with the thermal pads 351, 353 contacting the mold 344 and preventing mold compound from covering the thermal pads.

The struts 385, 387 shown in FIGS. 4H-4J form an additional arrangement and are not required for all arrangements, but can increase reliability and reduce or prevent mold compound from covering the thermal pads during molding processes used to form a semiconductor device package. The slot 381 is shown with a sloped shape that matches a portion of the strut 387 to engage the strut 387 and increase stability.

FIGS. 5A-5D illustrate, in cross-sectional and projection views, details of an alternative example semiconductor device package of an arrangement.

FIG. 5A illustrates, in a side view, a portion of an alternative arrangement for a semiconductor device package at an intermediate stage of assembly. In FIG. 5A, instead of mounting the semiconductor die 305 facing away from the top surface of the heat slug 321, as shown in FIG. 5A the alternative arrangement mounts the semiconductor die 305 facing the board side of the heat slug 321. The dashed line 330 indicates that the view is a partial view, the low voltage section 3072 of the leadframe 307 includes leads of interior lead portion 331 that will extend to exterior leads that will form terminals in a later step, described below. The high voltage section 3071 of the leadframe 307 is shown with the heat slug 321 mounted on the board side surface of the leadframe 307, (which faces upwards in the orientation of FIG. 5A.) Welding or brazing operations can be used to attach the heat slug 321 and the leadframe 307, alternatively solder can be used. An insulating material 313, which is similar to insulating material 314 in FIG. 4G, for example, is shown. The semiconductor die 305 is mounted on the board side surface of the insulating material 313, which can be a polyimide tape or film, a FR4 or BT resin circuit board material, a ceramic or a laminate. In a useful example, Kapton® or another polyimide film or tape can be used. Other dielectric materials can be used for the insulating material 313.

As shown in FIG. 5A, the semiconductor die 305 is mounted using a die attach material 317 to the insulating material 313 and is positioned so that the Hall element 308, which is formed within the semiconductor die 305, is positioned proximate to the heat slug 321. When a current to be sensed flows through the heat slug 321, the Hall element 308 will be exposed to the magnetic field that is caused by the current flow, and the circuitry within the semiconductor die 305 will output a voltage signal corresponding to the current on one of the terminals 310 of the low voltage section 3072. The semiconductor die 305 can implement a Hall sensor using circuitry such as is shown in FIG. 1C and output a voltage on a low voltage lead of the leadframe 307 that corresponds to the magnitude of the current flowing through the heat slug 321. While in FIG. 1C two Hall elements 1081, 1082 are shown with a differential amplifier, in an alternative a single Hall element 308 can be used as shown in FIG. 5A.

Wire bonds 325 are shown in FIG. 5A coupling bond pads (not shown for clarity of illustration, but see for example bond pads 102 in FIG. 1B) of the semiconductor die 305 to leads of the interior lead portion 331 of the low voltage section 3072 of the leadframe 307. Note that the alternative arrangement shown in FIG. 5A is similar to the arrangement of FIGS. 3A-3B except that the position of the semiconductor die 305 is now on the board side of the insulating material (313 in this example).

FIG. 5B illustrates the elements of FIG. 5A after a molding step to form the mold compound 323 around the semiconductor die 305. In an example molding process, the leadframe 307, which is attached to heat slug 321, the semiconductor die 305 and the wire bonds 325 are placed in a mold of a transfer mold tool. The mold compound 323 forms a solid package body around the leadframe 307, the heat slug 321, and the semiconductor die 305. FIG. 5B shows the mold compound 323, in the partial view indicated by dashed line 330, with a board side surface of the heat slug 321 exposed from the board side of the mold compound 323, forming a thermal pad 351. When the semiconductor device package is mounted to a board or module, the thermal pad 351 can be placed on and thermally couple to a corresponding thermal pad on the board, to enhance thermal dissipation from the semiconductor device package. Note that in FIG. 5B, the elements are shown with the board side facing up, in correspondence with the orientation of FIG. 5A.

FIG. 5C illustrates, in a further side view, a completed semiconductor device package 300 including the elements of FIG. 5C, shown after singulation, trim and form processes form the external terminals 322, 310. Semiconductor device package 500 has a top surface 328 and a board side surface 326. The thermal pad 351, the board side of the heat slug 321, is exposed from the mold compound 323 at the board side surface 326. (Note that the elements of FIG. 5C are rotated compared to the orientation shown in FIGS. 5A-5B, in FIG. 5C the semiconductor device package is shown with the board side surface 326 facing downwards, positioned as it will be positioned when mounted to a board or module.) The semiconductor device package 500 has terminals 322 that extend from the high voltage section 3071 of the leadframe 307. The leadframe 307 is attached to the heat slug 321, and is electrically isolated from the low voltage section 3072 of the leadframe 307. Terminals 310 extend from the low voltage section 3072. In using SOIC semiconductor device packages such as semiconductor device package 500, some advantages include that the gull wing shape of the terminals 322, 310 act as thermal “springs”, allowing some movement and thereby increasing board level reliability (BLR) of the mounted semiconductor device packages, because the gull wing shaped terminals allow some movement due to thermal expansion or board motion without breaking solder joints, which can cause “hot spots” or even form opens.

The semiconductor die 305 is shown mounted on insulating material 313 with the bond pads facing the board side surface 326, with the wire bonds 325 coupling bond pads on the device side of the semiconductor die 305 to leads of the low voltage section 3072 of the leadframe 307. The terminals 310 are coupled to the low voltage section 3072 of the leadframe and are formed from the exterior portion of leads that extend from the interior portion through the mold compound 323 and outside the mold compound 323. The semiconductor die 305 is attached to the insulating material 313 with die attach material 317. The example semiconductor device package 500 shown in FIG. 5C is a small outline integrated circuit (SOIC) type package and may be formed to mount to a board using a standard SOIC footprint, reducing costs of assembly by using existing board layout patterns. The Hall element 308 is shown positioned proximate to the heat slug 321, so that the Hall sensor formed by the semiconductor die 305 can respond to a magnetic field formed by current flowing through the heat slug 321 and the high voltage section 3071 of the leadframe 307.

FIG. 5C also illustrates the advantages of the upset design of leadframe 307 used in the arrangements. The terminals 322, 310 in FIG. 5C of the semiconductor device package 500 extend from the outermost ends towards the semiconductor device package as leads of the leadframe 307, and (as shown in FIG. 5B, see interior lead portion 331 for example), form interior leads inside the mold compound 323. The leads on the high voltage section 3071 form a single element inside the device package, one for the input portion, and one for the output portion, of the high voltage terminals. The leadframe 307 has an “upset” design, in transitioning from the exterior of the package, where the leads extend through the middle of the package body of mold compound 323, to the interior, where the leads lie in a plane over the top surface of the heat slug 321, an angled upset is used, as shown in dashed circle 561 for the high voltage section 3071 in FIG. 5C, and dashed circle 562 for the low voltage section 3072. The upset leadframe design is optional, but advantageously provides the ability to use a heat slug 321 with a thickness “Ths” that is greater than half the overall thickness of the package “Tp.” In an example, the integral heat slug 321 may have a thickness of about 1 millimeter. Use of the upset angled portions shown in circles 561, 562 in the leadframe 307 allows for a thicker heat slug 321 in a standard package thickness, for example a package thickness Tp of about 1.5 millimeters. In an alternative arrangement formed without the upset design, with a planar leadframe, the overall package thickness may need to be increased to accommodate the heat slug thickness, but use of the flexible connect portion in the leads of the high voltage portions will nonetheless attain the advantages of the arrangements, allowing the heat slug to move while maintaining the alignment of the leads.

FIG. 5D illustrates, in a projection view from a board side, the semiconductor device package 500 of FIG. 5C. (Note that the elements of FIG. 5D are shown rotated with the board side facing upwards, in contrast to FIG. 5C, which is shown in the orientation as the device would be mounted, with the board side facing downwards.) In FIGS. 5C-5D the mold compound 323 is shown as transparent so that the other elements are visible in the drawing, note that mold compound is typically opaque (see, for example, mold compound 223 forming the semiconductor device package 200 in FIGS. 2A-2B). In FIG. 5D, the input terminals 322 are arranged to be coupled to an input current IN+ and are part of the high voltage section 3071 of the leadframe 307. The input terminals 322 are formed from leads shown extending into the mold compound 323 to form interior lead portion 375. The output terminals 324 of the output portion 3076 of the high voltage section 3071 are arranged to be coupled to an output current IN−. The output terminals 324 are formed from leads that extend into the mold compound 323 and form interior lead portion 376. The flexible connect portions 378 and 377 are shown on the top surface of the heat slug 321 (facing downwards in FIG. 5D, as the semiconductor device package 500 is oriented with the board side surface facing upwards in this view so that the semiconductor die 305 is more visible.) The input portion 3075 of the high voltage section 3071 of the leadframe 307 is shown attached to the heat slug 321 by mount portion 379. The output portion 3076 of the high voltage section 3071 of the leadframe 307 is shown with the mount portion 380 attaching it to the heat slug 321. The wire bonds 325 are shown coupling the semiconductor die to leads of the interior lead portion 331 of the low voltage section 3072 of the leadframe 307, and the leads of the interior lead portion 331 extend from the mold compound 323 to form the external terminals 310 for the low voltage signals. The Hall element 308 is shown within the semiconductor die 305 and positioned proximate to the heat slug 321 and is arranged to sense the magnetic field caused by current flowing through the heat slug 321. The flexible connect portions 377, 378 and the interior lead portions 375, 376 lie over the top surface of the heat slug 321 but are not fixed to it, while the mount portions 379, 380 are attached to the heat slug 321 by welding, brazing, or solder. If the heat slug 321 moves, for example if it is displaced during a transfer molding operation to form the mold compound 323 of the semiconductor device package 500, the flexible connect portions 377, 378 can move while leaving the interior lead portions 375, 376 aligned and in the correct position. After the molding is complete, the use of the arrangements results in reduced delamination and cracking defects in the molded packages, and increased yield.

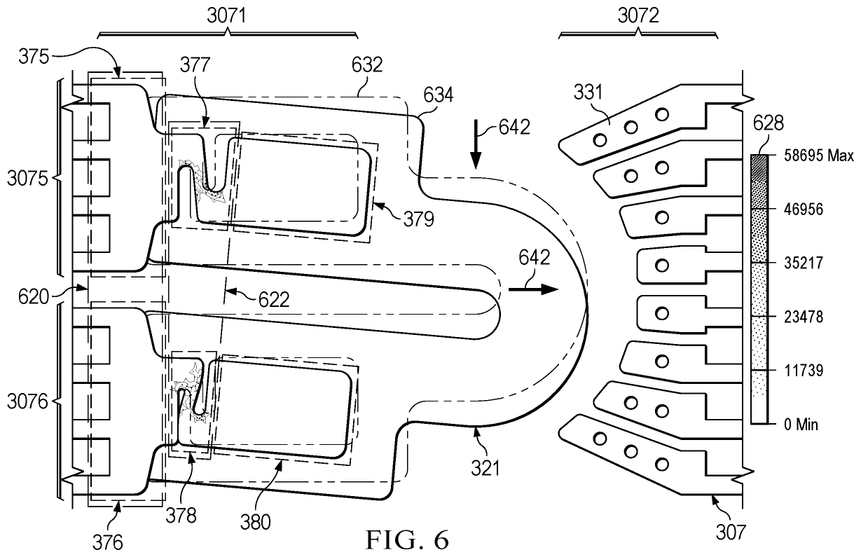

FIG. 6 illustrates the results of a mechanical simulator illustrating features of the arrangements. In FIG. 6, the heat slug 321 and a portion of the leadframe 307 are shown in a plan view, with force arrows 642 indicating force applied to the heat slug 321 corresponding to mold compound pressing against the heat slug. The leadframe 307 is shown with the high voltage section 3071 and low voltage section 3072 shown with leads 331 in the low voltage section. The high voltage section includes an input portion 3075 including interior lead portion 375, flexible connect portion 377, and mount portion 379 and an output portion 3076 including interior lead portion 376, flexible connect portion 378 and mount portion 380. The simulation results are shown by shading the elements and the shading corresponds to the stress in units of MPa, with the darkest shade indicating zero stress (see the key 628 in FIG. 6). The area 620 illustrates the stress on a bonding portion where the high voltage leads will bond with the mold compound at an exterior surface of the package body, and the box 622 illustrates the stress on the flexible connect portions 377 and 378. The stress is indicated by shading as shown in the key 628. The mechanical stress on the bonding portion is very low, while the stress on the flexible connect portions is only slightly increased over the remaining elements. Use of the arrangements allows the heat slug 321 to move from an initial position shown as 632 in the illustration to a final position shown as 634 in the illustration without significant mechanical stress on the flexible connect portions 378, 377 as shown in the box 622, and with almost no mechanical stress on the bonding area of the leads in box 620. The leads 375, 376 are not displaced by the movement of the heat slug 321, so that delamination or package crack defects are reduced or eliminated. After the mold compound cures, the integral heat slug 321 can be slightly displaced, and the flexible connect portions 377, 378 can be locked in place, even is slightly moved from an initial position, by the cured thermoset mold compound.

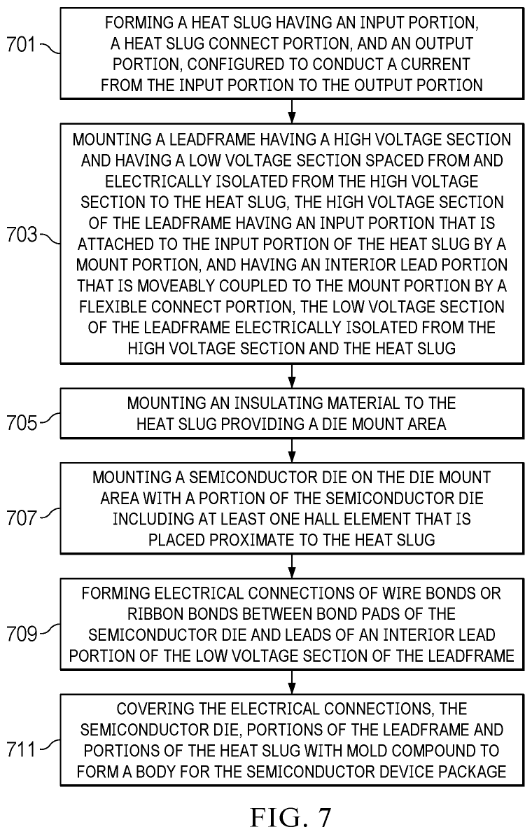

FIG. 7 illustrates, in a flow diagram, steps for forming a semiconductor device package of the arrangements. In FIG. 7, at step 701, the method begins by forming a heat slug having an input portion, a heat slug connect portion, and an output portion, arranged to conduct a current from the input portion to the output portion. (See, for example, in FIG. 4A heat slug 321 has an input portion 3212, and output portion 3211 that is connected by heat slug connect portion 3213 of the heat slug 321.)

At step 703, the method continues by mounting a leadframe having a high voltage section and having a low voltage section spaced from and electrically isolated from the high voltage section to the heat slug, the high voltage section of the leadframe having an input portion that is attached to the input portion of the heat slug by a mount portion, and having an interior lead portion that is coupled to the mount portion by a flexible connect portion. (See, for example, FIG. 4A, where the leadframe 307 has high voltage section 3071 and low voltage section 3072, with the input portion 3075 of high voltage section 3071, and the input portion 3075 has an interior lead portion 375 that is connected to the mount portion 379 by flexible connect portion 377).

At step 705, the method continues by mounting an insulating material to the heat slug providing a die mount area. (See, for example, FIG. 4B with insulating material 314 mounted to the heat slug 321).

At step 707, the method continues by mounting a semiconductor die on the die mount area with a portion of the semiconductor die including at least one Hall element that is placed proximate to the heat slug. (See for example FIG. 4D, semiconductor die 305 includes a Hall element 308 overlying the heat slug connect portion of the heat slug 321, or FIG. 5A, where semiconductor die 305 is placed with the Hall element 308 proximate to the heat slug 321.)

At step 709, the method continues by forming electrical connections of wire bonds or ribbon bonds between bond pads of the semiconductor die and leads of an interior lead portion of the low voltage section of the leadframe. (See, for example, FIG. 4E with wire bonds 325, or wire bonds 325 in FIG. 5A, in the alternative arrangement).

At step 711, the method ends by covering the electrical connections, the semiconductor die, portions of the leadframe and portions of the heat slug with mold compound to form a body for the semiconductor device package. (See mold compound 323 in FIG. 3B, for example, and see mold compound 323 in FIG. 5B).

The use of the arrangements provides a semiconductor device package including one or more Hall elements forming sensors with an integral heat slug and a flexible connect portion in the high voltage section of a leadframe. The packaged semiconductor devices can be current sensors configured for high power or high current applications such as currents of greater than an Ampere and up to 100 Amperes or higher. The arrangements are formed using existing methods, materials and tooling for making the devices and are cost effective. The leadframes and heat slugs are formed of materials that are readily available. By providing the flexible connect portion of the leadframes in the high voltage section, the movement of the heat slugs during transfer molding to form the packages does not cause the leads to move and become misaligned, and use of the arrangements therefore reduces defective semiconductor device packages during the packaging process, and further reduces delamination and package cracking during production and in use. Use of the arrangements provides an economical and robust integrated Hall current sensor device for high power applications. The packaged semiconductor devices can be used with a variety of semiconductor package types, including leaded packages such as SOIC, wide SOIC, and SOP packages, and including no-lead packages including QFN and SON packages.

Modifications are possible in the described arrangements, and other alternative arrangements are possible within the scope of the claims.

What is claimed is:

1. A method of forming a semiconductor device package, comprising:
forming a heat slug having an input portion, a heat slug connect portion, and an output portion, configured to conduct a current from the input portion to the output portion;
mounting a leadframe having a high voltage section and having a low voltage section spaced from and electrically isolated from the high voltage section to the heat slug, the high voltage section of the leadframe having an input portion that is attached to the input portion of the heat slug by a mount portion, and having an interior lead portion that is connected to the mount portion by a flexible connect portion;
mounting an insulating material to the heat slug providing a die mount area;
mounting a semiconductor die on the die mount area, the semiconductor die including at least one Hall element that is placed proximate to the heat slug;
forming electrical connections of wire bonds or ribbon bonds between bond pads of the semiconductor die and leads of an interior lead portion of the low voltage section of the leadframe; and
covering the electrical connections, the semiconductor die, portions of the leadframe and portions of the heat slug with mold compound to form a body for the semiconductor device package.

2. The method of claim 1, and further comprising attaching an output portion of the high voltage section of the leadframe spaced from the input portion to the output portion of the heat slug with another mount portion at an interior end of the output portion, and the output portion of the high voltage section further comprises another interior lead portion that is connected to another mount portion by another flexible connect portion.

3. The method of claim 1, wherein during covering the electrical connections, the semiconductor die, and portions of the leadframe with mold compound, the mount portion of the input portion of the high voltage section moves with any movement of the heat slug, while the interior lead portion of the input portion remains in place due to movement of the flexible connect portion.

4. The method of claim 1, wherein mounting the semiconductor die having the at least one Hall element on the die mount area further comprises mounting the semiconductor die on a top side surface of the insulating material with the bond pads facing away from the top side surface.

5. The method of claim 1, wherein mounting the semiconductor die having the at least one Hall element on the die mount area further comprises mounting the semiconductor die on a board side surface of the insulating material with the bond pads facing towards the board side surface of the semiconductor device package.

6. The method of claim 1, wherein the insulating material is a polyimide, a polyimide film, a bismaleimide triazine (BT) resin laminate or a glass-reinforced fire-retardant epoxy (FR4) laminate.

7. The method of claim 1, wherein mounting a leadframe having a high voltage section and having a low voltage section spaced from and electrically isolated from the high voltage section to the heat slug, the high voltage section of the leadframe having an input portion that is attached to the input portion of the heat slug by a mount portion, and having an interior lead portion that is connected to the mount portion by a flexible connect portion further comprises the flexible connect portion that has an “S” shape when viewed in a plan view.

8. The method of claim 1, wherein covering the electrical connections, the semiconductor die, and portions of the leadframe and the heat slug with mold compound to form a body for the semiconductor device package further comprises leaving a board side surface of the heat slug exposed from the mold compound to form a thermal pad.

9. The method of claim 1, wherein the heat slug is of copper or an alloy thereof.

10. The method of claim 1, and further comprising forming high voltage input terminals extending from the interior lead portion of the input portion of the high voltage section of the leadframe, wherein the high voltage input terminals include exterior leads extending through the mold compound to the interior lead portion of the input portion of the high voltage section.

11. The method of claim 1, and further comprising forming mechanical struts extending from a support bar of the leadframe, and when the leadframe is mounted to the heat slug, the mechanical struts extend over the heat slug, the mechanical struts on opposite sides of the heat slug.

12. The method of claim 11, wherein the heat slug has slots configured to engage the mechanical struts.

13. The method of claim 1, wherein the leadframe comprises copper, aluminum, stainless steel, steel, or alloys thereof.

14. An apparatus, comprising:
a leadframe having a board side surface and an opposite top surface, the leadframe having a high voltage section and a low voltage section spaced from and electrically isolated from the high voltage section;
a heat slug mounted to the high voltage section, the heat slug having an input portion and an output portion spaced from the input portion and coupled to the input portion by a heat slug connect portion, the high voltage section of the leadframe having an input portion connected to the input portion of the heat slug at an interior end by a mount portion, the input portion of the leadframe further comprising an interior lead portion that is connected to the mount portion by a flexible connect portion, the high voltage section of the leadframe having an output portion connected to the output portion of the leadframe at an interior end by another mount portion, the output portion of the high voltage section of the leadframe further comprising another interior lead portion that is connected to the another mount portion by another flexible connect portion;
an insulating material mounted to the heat slug and providing a die mount area for a semiconductor die;
a semiconductor die having a Hall element mounted to the die mount area and positioned so that the Hall element is proximate to the heat slug;
electrical connections of wire bonds or ribbon bonds between bond pads of the semiconductor die and leads of an interior lead portion of the low voltage section of the leadframe; and
mold compound covering the semiconductor die, portions of the leadframe, and portions of the heat slug while a board side surface of the heat slug is exposed forming a thermal pad for a semiconductor device package.

15. The apparatus of claim 14, wherein the input portion of the high voltage section of the leadframe, the output portion of the high voltage section of the leadframe, and the heat slug are configured to carry a current to the heat slug connect portion that is proximate to the semiconductor die.

16. The apparatus of claim 15 wherein the heat slug connect portion is proximate to the Hall element on the semiconductor die.

17. The apparatus of claim 14, wherein the flexible connect portion of the leadframe has an “S”, “Z”, “C”, “V”, “L” or “U” shape when viewed in a plan view from a top side surface.

18. The apparatus of claim 14, wherein the Hall element on the semiconductor die is a first Hall element, and further comprising a second Hall element on the semiconductor die spaced from the first Hall element, the first Hall element and the second Hall element positioned proximate to the heat slug connect portion.

19. The apparatus of claim 18, wherein the first Hall element and the second Hall element are configured to output a voltage corresponding to magnetic field caused by a current flowing in the heat slug.

20. The apparatus of claim 14, and further comprising:
high voltage input terminals formed by leads extending through the mold compound from the interior lead portion of the input portion of the high voltage section of the leadframe;
high voltage output terminals formed by leads extending through the mold compound from another interior lead portion of the output portion of the high voltage section of the leadframe; and
low voltage terminals formed by leads extending through the mold compound from the interior lead portion of the low voltage section of the leadframe.

21. The apparatus of claim 20, wherein the high voltage input terminals, the high voltage output terminals, and the low voltage terminals have gull wing shapes.

22. The apparatus of claim 20, wherein the semiconductor device package is a small outline integrated circuit (“SOIC”) package or a wide SOIC package.

23. The apparatus of claim 20, and further comprising:
struts extending from support bars and extending over the heat slug, the struts on opposite sides of the heat slug.

24. The apparatus of claim 23, and further comprising slots in the heat slug configured to receive the struts and to contact the struts.

25. A Hall current sensor device, comprising:
a leadframe having a board side surface and an opposite top surface, the leadframe having a high voltage section and a low voltage section spaced from and electrically isolated from the high voltage section;
a heat slug mounted to the high voltage section, the heat slug having an input portion and an output portion spaced from the input portion and coupled to the input portion by a heat slug connect portion, the high voltage section of the leadframe having an input portion connected to the input portion of the heat slug at an interior end by a mount portion, the input portion of the leadframe further comprising an interior lead portion that is connected to the mount portion by a flexible connect portion, the high voltage section of the leadframe having an output portion connected to the output portion of the leadframe at an interior end by another mount portion, the output portion of the high voltage section of the leadframe further comprising another interior lead portion that is connected to the another mount portion by another flexible connect portion;
an insulating material over the heat slug and forming a die mount area for a semiconductor die;
a semiconductor die having a Hall element mounted to the die mount area, the semiconductor die having bond pads on a device side surface;
electrical connections comprising wire bonds or ribbon bonds between the bond pads of the semiconductor die and an interior portion of a set of leads of the low voltage section of the leadframe; and
mold compound covering the electrical connections, the semiconductor die, portions of the leadframe, and a portion of the heat slug to form a semiconductor device package, while a portion of the heat slug is exposed from the mold compound forming a thermal pad for a semiconductor device package.

26. The Hall current sensor device of claim 25, wherein the semiconductor die is mounted on the insulating material with the bond pads facing away from the board side surface of the leadframe.

27. The Hall current sensor device of claim 25, wherein the semiconductor die is mounted with the bond pads facing towards from the board side surface of the leadframe.
